(19) United States
(12) Patent Application Publication
(10) Pub. No.: US 2025/0183206 A1
(43) Pub. Date: Jun. 5, 2025

(54) SEMICONDUCTOR CHIP AND SEMICONDUCTOR PACKAGE INCLUDING THE SAME

(71) Applicant: SAMSUNG ELECTRONICS CO., LTD., Suwon-si (KR)

(72) Inventors: Enbin JO, Suwon-si (KR); Wonil LEE, Suwon-si (KR); Namhoon KIM, Suwon-si (KR)

(73) Assignee: SAMSUNG ELECTRONICS CO., LTD., Suwon-si (KR)

(21) Appl. No.: 18/962,714

(22) Filed: Nov. 27, 2024

(30) Foreign Application Priority Data
Nov. 30, 2023 (KR) 10-2023-0171820

(51) Int. Cl. H01L 23/00; H01L 23/48

(52) U.S. Cl. CPC H01L 24/05; H01L 23/481; H01L 24/03; H01L 24/08; H01L 2224/02141; H01L 2224/0345; H01L 2224/05547; H01L 2224/0557; H01L 2224/05576; H01L 2224/05647; H01L 2224/05655; H01L 2224/08146

(57) ABSTRACT

A semiconductor chip includes a semiconductor substrate, a pad insulating layer on the semiconductor substrate, a through electrode at least partially penetrating the semiconductor substrate and the pad insulating layer, and a bonding pad on an upper portion of the through electrode and electrically and physically coupled with the through electrode. The pad insulating layer includes a first insulating layer, a second insulating layer on the first insulating layer, and a buffer layer on the second insulating layer. The first insulating layer includes a first material and the second insulating layer includes a second material different from the first material.

### CROSS-REFERENCE TO RELATED APPLICATIONS

This application claims benefit of priority under 35 U.S.C. § 119 to Korean Patent Application No. 10-2023-0171820, filed on Nov. 30, 2023, in the Korean Intellectual Property Office, the disclosure of which is incorporated by reference herein in its entirety.

### BACKGROUND

### 1. Field

The present disclosure relates generally semiconductor devices, and more particularly, to a semiconductor chip and a semiconductor package including stacked semiconductor chips.

### 2. Description of Related Art

In order to potentially meet an increase in demand for miniaturized, multifunctional, and/or high-performance electronic products, semiconductor packages may need to have a relatively high degree of integration and/or perform at a relatively high speed. Consequently, semiconductor packages having stacked semiconductor chips may have been developed to potentially address the need for highly integrated and/or high speed devices.

### SUMMARY

One or more example embodiments of the present disclosure provide a semiconductor chip with relatively improved thermal characteristics, when compared to related semiconductor chips, and a semiconductor package including stacked semiconductor chips.

According to an aspect of the present disclosure, a semiconductor chip includes a semiconductor substrate, a pad insulating layer on the semiconductor substrate, a through electrode at least partially penetrating the semiconductor substrate and the pad insulating layer, and a bonding pad on an upper portion of the through electrode and electrically and physically coupled with the through electrode. The pad insulating layer includes a first insulating layer, a second insulating layer on the first insulating layer, and a buffer layer on the second insulating layer. The first insulating layer includes a first material and the second insulating layer includes a second material different from the first material.

According to an aspect of the present disclosure, a semiconductor chip includes a semiconductor substrate including a first surface and a second surface facing the first surface, a through electrode at least partially penetrating the semiconductor substrate, a pad insulating layer at least partially surrounding a portion of a sidewall of the through electrode and disposed on the first surface of the semiconductor substrate, a bonding pad on an upper portion of the through electrode and electrically and physically coupled with the through electrode, and a wiring structure including a wiring insulating layer disposed on the second surface of the semiconductor substrate, a wiring line, and a wiring via. The wiring line and the wiring via are provided in the wiring insulating layer. The wiring line and the wiring via are electrically coupled with the through electrode. The pad insulating layer includes a first insulating layer, a second insulating layer on the first insulating layer, and a buffer layer on the second insulating layer and including a silicon nitride film. The buffer layer is spaced apart from the first insulating layer with the second insulating layer therebetween.

According to an aspect of the present disclosure, a semiconductor package includes a first semiconductor chip and a second semiconductor chip bonded to the first semiconductor chip. The first semiconductor chip includes a first semiconductor substrate including a first surface and a second surface opposite to the first surface, a first protective insulating structure on the first surface of the first semiconductor substrate, a first through electrode at least partially penetrating the first semiconductor substrate and the first protective insulating structure, and a first bonding pad on an upper portion of the first through electrode. The second semiconductor chip includes a second semiconductor substrate and a second bonding pad in contact with the first bonding pad. The first protective insulating structure includes a first insulating layer including a first material, a second insulating layer on the first insulating layer and including a second material different from the first material, and a buffer layer on the second insulating layer and including a third material different from the second material.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1A is a cross-sectional view schematically illustrating a semiconductor chip, according to embodiments;

FIG. 1B is an enlarged view illustrating a region indicated as “EX1” in FIG. 1A, according to embodiments;

FIG. 1C is a plan view of the semiconductor chip of FIG. 1A, according to embodiments;

FIG. 2A is a cross-sectional view schematically illustrating a semiconductor chip, according to embodiments;

FIG. 2B is an enlarged view illustrating a region indicated as “EX2” in FIG. 2A, according to embodiments;

FIG. 3A is a cross-sectional view schematically illustrating a semiconductor chip, according to embodiments;

FIG. 3B is an enlarged view illustrating a region indicated as “EX3” in FIG. 3A, according to embodiments;

FIG. 4 is a cross-sectional view schematically illustrating a semiconductor chip, according to embodiments;

FIG. 5 is a cross-sectional view schematically illustrating a semiconductor chip, according to embodiments;

FIG. 6 is a cross-sectional view schematically illustrating a semiconductor chip, according to embodiments;

FIGS. 7A, 7B, 7C, 7D and 7E are diagrams illustrating a method of manufacturing a semiconductor chip, according to embodiments;

FIGS. 8A and 8B are diagrams illustrating a method of manufacturing a semiconductor chip, according to embodiments;

FIGS. 9A, 9B, 9C, 9D, and 9E are diagrams illustrating a method of manufacturing a semiconductor chip, according to embodiments;

FIG. 10A is a cross-sectional view illustrating a semiconductor package, according to embodiments;

FIG. 10B is an enlarged view illustrating a region indicated as “EX4” in FIG. 10A, according to embodiments;

FIG. 11A is a cross-sectional view illustrating a semiconductor package, according to embodiments;

FIG. 11B is an enlarged view illustrating a region indicated as “EX5” in FIG. 11A, according to embodiments;

FIG. 12 is a cross-sectional view illustrating a semiconductor package, according to embodiments;

FIG. 13A is a cross-sectional view illustrating a semiconductor package, according to embodiments; and

FIG. 13B is an enlarged view illustrating a region indicated as “EX6” in FIG. 13A, according to embodiments.

### DETAILED DESCRIPTION

The present disclosure is described with reference to accompanying drawings, in which embodiments of the present disclosure are shown. The present disclosure may, however, be embodied in many different forms and should not be construed as being limited to the embodiments set forth herein, rather, these embodiments are provided so that this disclosure may be thorough and complete, and may fully convey the concept of the present disclosure to those skilled in the art. In the drawings, the relative sizes of layers and regions may be exaggerated for clarity. In addition, like reference numerals in the drawings may denote like elements.

One element referred to as being “connected to”, “coupled to”, or “coupled with” another element may include a case of being directly connected to or coupled to the other element or a case where another element is interposed therebetween. Conversely, one element being “directly connected to” or “directly coupled to” another element may indicate that no other elements are interposed therebetween.

As used herein, the term “and/or” may include each of items and one or more of all combinations thereof. In addition, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. Furthermore, such terms as “1st” and “2nd,” or “first” and “second” may be used to simply distinguish a corresponding component from another, and does not limit the components in other aspect (e.g., importance or order).

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

The case where an element and/or layer is said to be “on” or “on the top of ˜” another element or layer may include a case where the element and/or layer is directly on the other element or layer and a case where other layers or elements are interposed therebetween. Conversely, an element being “directly on” or “directly on the top of ˜” another element indicates the case where no other elements or layers are interposed therebetween.

While such terms as “first,” “second,” etc., may be used to describe various elements, components and/or sections, such elements, components and/or sections must not be limited to the above terms. The above terms are used only to distinguish one element, component, or section from another. Accordingly, in the present disclosure, a first element, a first component, or a first section may also be a second element, a second component, or a second section.

The terms used in the present disclosure are merely used to describe particular embodiments, and are not intended to limit the present disclosure. As used herein, an expression used in the singular may encompass the expression of the plural. In addition, it is to be understood that terms such as “comprises” and/or “comprising” may be intended to indicate the existence of the disclosed components, steps, operations and/or elements, and may not be intended to preclude the possibility that one or more other components, steps, operations and/or devices may exist and/or may be added.

Unless otherwise defined, all terms (including technical and scientific terms) used herein may be used with meanings that may be commonly understood by those skilled in the art to which the present disclosure pertains. In addition, terms defined in commonly used dictionaries may not be interpreted ideally or excessively unless clearly specifically defined.

Hereinafter, embodiments of the present disclosure are described with reference to the accompanying drawings.

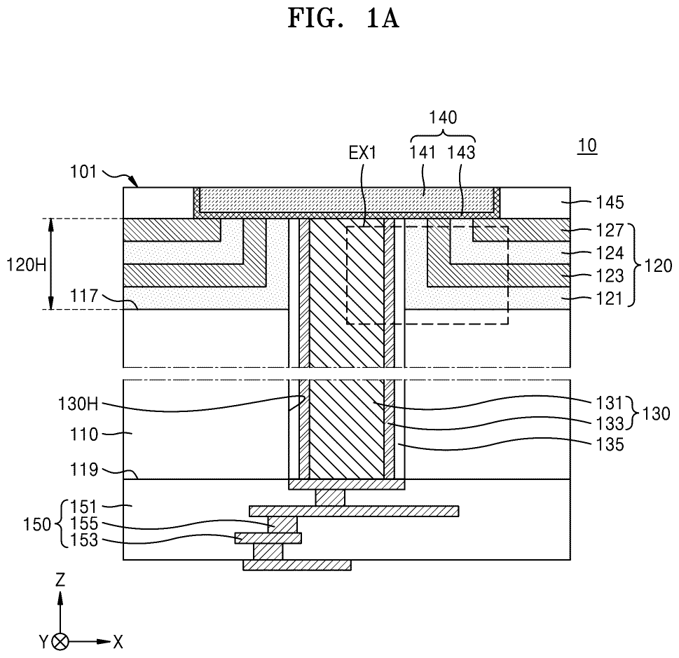

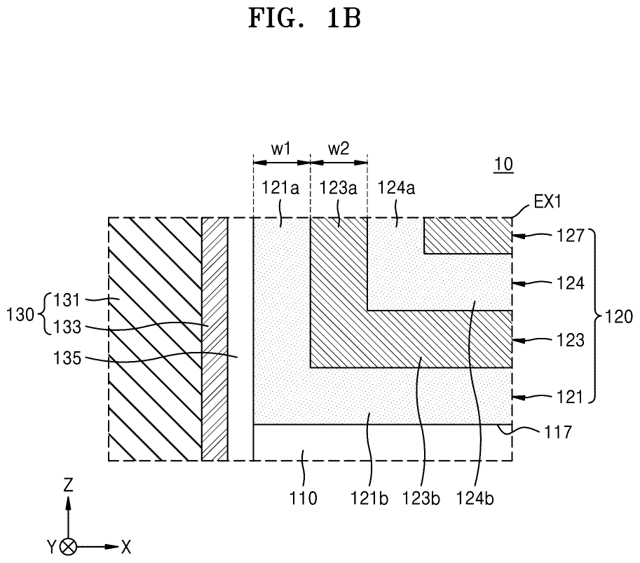

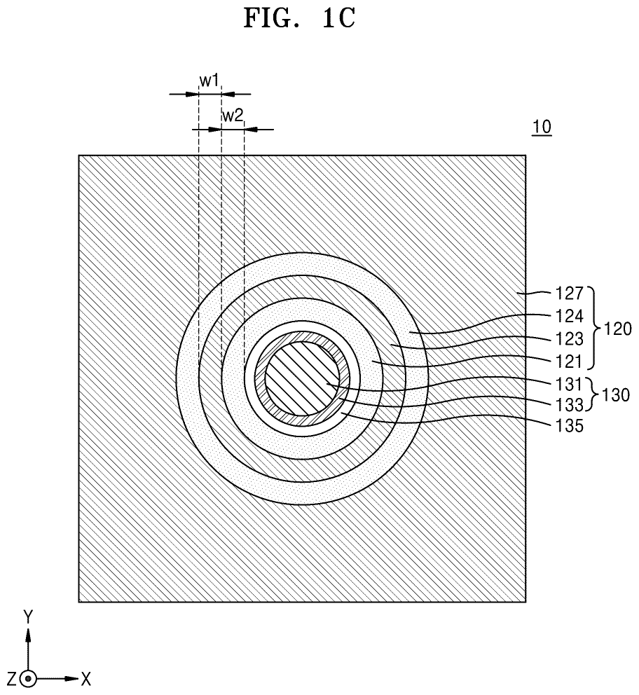

FIG. 1A is a cross-sectional view schematically illustrating a semiconductor chip 10, according to embodiments. FIG. 1B is an enlarged view illustrating a region indicated as “EX1” in FIG. 1A, according to embodiments. FIG. 1C is a plan view of the semiconductor chip 10 of FIG. 1A, according to embodiments.

Referring to FIGS. 1A, 1B, and 1C, the semiconductor chip 10 may include a semiconductor substrate 110, a pad insulating layer 120, a through electrode 130, a bonding pad 140, and a wiring structure 150.

The semiconductor substrate 110 may include a first surface 117 and a second surface 119, which may be opposite to each other. The first surface 117 of the semiconductor substrate 110 may be a backside surface of the semiconductor substrate 110, and the second surface 119 of the semiconductor substrate 110 may be a front-side surface of the semiconductor substrate 110. The first surface 117 of the semiconductor substrate 110 may be an inactive surface of the semiconductor substrate 110, and the second surface 119 of the semiconductor substrate 110 may be an active surface of the semiconductor substrate 110. However, the present disclosure is not limited in this regard, and the first surface 117 of the semiconductor substrate 110 may be the front-side surface of the semiconductor substrate 110 and/or the active surface of the semiconductor substrate 110, and the second surface 119 of the semiconductor substrate 110 may be the backside surface of the semiconductor substrate 110 and/or the inactive surface of the semiconductor substrate 110.

Hereinafter, a direction parallel to the first surface 117 of the semiconductor substrate 110 may be referred to as a horizontal direction (e.g., a first horizontal direction X and/or a second horizontal direction Y), and a direction perpendicular to the first surface 117 of the semiconductor substrate 110 may be referred to as a vertical direction Z. In addition, a horizontal width of any member may refer to a length along the first horizontal direction X and/or the second horizontal direction Y, and a vertical height of any member may refer to a length along the vertical direction Z.

The semiconductor substrate 110 may be formed from a semiconductor wafer. The semiconductor substrate 110 may include, for example, silicon (Si). Alternatively or additionally, the semiconductor substrate 110 may include a semiconductor element, such as, but not limited to, germanium (Ge), or a compound semiconductor such as, but not limited to, silicon carbide (SiC), gallium arsenide (GaAs), indium arsenide (InAs), and indium phosphide (InP). The semiconductor substrate 110 may include a conductive region, for example, a well doped with impurities and/or a structure doped with impurities. Alternatively or additionally, the semiconductor substrate 110 may include various device isolation structures, such as, but not limited to, a shallow trench isolation (STI) structure.

The pad insulating layer 120 may be provided on the first surface 117 of the semiconductor substrate 110. The pad insulating layer 120 may cover the first surface 117 of the semiconductor substrate 110. In addition, the pad insulating layer 120 may surround a sidewall of the through electrode 130 protruding from the first surface 117 of the semiconductor substrate 110.

In some embodiments, the pad insulating layer 120 may include an oxide and/or a nitride. For example, the pad insulating layer 120 may include at least one of silicon oxide (SiO), silicon nitride (SiN), silicon carbonitride (SiCN), silicon carbonate (SiCO), a polymer material, or the like. As used herein, each of the terms “GaAs”, “InAs”, “InP”, “SiC”, “SiO,” “SiN,” “SiCN”, “SiCO”, and the like may refer to materials including elements included in respective terms, and may not be chemical formulas representing stoichiometric relationships. For example, the polymer material may be benzocyclobutene (BCB), polyimide (PI), polybenzoxazole (PBO), silicone, and/or epoxy.

In some embodiments, the pad insulating layer 120 may include a plurality of insulating layers (e.g., a first insulating layer 121, a second insulating layer 123, and a third insulating layer 124), and a buffer layer 127, which may be sequentially stacked on the first surface 117 of the semiconductor substrate 110. The number of insulating layers 121 to 124 that may be included in the pad insulating layer 120 is not limited thereto and may include an odd number of insulating layers of three (3) or more.

Among the plurality of insulating layers 121 to 124 included in the pad insulating layer 120, constituent materials of a pair of adjacent insulating layers may be different from each other. For example, the constituent materials of the first insulating layer 121 and the second insulating layer 123 may be different from each other, and the constituent materials of the second insulating layer 123 and the third insulating layer 124 may be different from each other. For example, in some embodiments, the first insulating layer 121 may include silicon oxide (SiO), the second insulating layer 123 may include silicon nitride (SiN), and the third insulating layer 124 may include silicon oxide (SiO). That is, the silicon oxide may include SiO₂, and the silicon nitride may include SiN. The buffer layer 127 may include a material having an etch selectivity to a bonding pad insulating layer 145 on the buffer layer 127. For example, the buffer layer 127 may include silicon nitride (SiN).

In some embodiments, an insulating layer including silicon oxide (SiO) from among the plurality of insulating layers 121 to 124 may be referred to as a pad oxide film, and an insulating layer including silicon nitride (SiN) from among the plurality of insulating layers 121 to 124 may be referred to as a pad nitride film. The pad insulating layer 120 may include at least one pad oxide film and at least one pad nitride film, which may be alternately stacked on the semiconductor substrate 110. For example, after a pad oxide film is stacked on the semiconductor substrate 110, a pad nitride film may be stacked on the pad oxide film, and then a pad oxide film may be stacked again.

In some embodiments, the first insulating layer 121, the second insulating layer 123, the third insulating layer 124, and the buffer layer 127 may be positioned below the bonding pad 140 to be in contact with the bonding pad 140.

In some embodiments, as shown in FIG. 1B, the first insulating layer 121 may include an upper first insulating layer 121a and a lower first insulating layer 121b. The second insulating layer 123 may include an upper second insulating layer 123a and a lower second insulating layer 123b. The third insulating layer 124 may include an upper third insulating layer 124a and a lower third insulating layer 124b. In some embodiments, the upper first insulating layer 121a, the upper second insulating layer 123a, and the upper third insulating layer 124a may each have a cylindrical shape surrounding a portion of the through electrode 130. In some embodiments, the lower first insulating layer 121b may extend in the first horizontal direction X and the second horizontal direction Y to cover the first surface 117 of the semiconductor substrate 110. The lower second insulating layer 123b may extend in the first horizontal direction X and the second horizontal direction Y to cover an upper surface of the lower first insulating layer 121b. The lower third insulating layer 124b may extend in the first horizontal direction X and the second horizontal direction Y to cover an upper surface of the lower second insulating layer 123b. The buffer layer 127 may be spaced apart from the sidewall of the through electrode 130 with the upper first insulating layer 121a, the upper second insulating layer 123a, and the upper third insulating layer 124a therebetween. Alternatively or additionally, the buffer layer 127 may be spaced apart from the first surface 117 of the semiconductor substrate 110 with the lower first insulating layer 121b, the lower second insulating layer 123b, and the lower third insulating layer 124b therebetween.

In some embodiments, a thickness of a pad oxide film may be within a range of about 2500 atom size (Å) to about 3500 Å, and a thickness of a pad nitride film may be within a range of about 1500 Å to about 2500 Å. In some embodiments, the thicknesses of the second insulating layer 123 and the buffer layer 127 may be less than the thicknesses of the first insulating layer 121 and the third insulating layer 124. In some embodiments, a thickness w1 of the first insulating layer 121 (or a distance between inner and outer peripheries of the upper first insulating layer 121a) may be within a range of about 2500 Å to about 3500 Å. A thickness w2 of the second insulating layer 123 (or a distance between inner and outer peripheries of the upper second insulating layer 123a) may be within a range of about 1500 Å to about 2500 Å. In some embodiments, a thickness 120H of the pad insulating layer 120 in the vertical direction Z may be within a range of about 0.6 micrometers (μm) to about 0.7 μm or within a range of about 0.8 μm to about 1.2 μm.

The through electrode 130 may penetrate the semiconductor substrate 110 and the pad insulating layer 120. The through electrode 130 may be provided in a through hole 130H of the semiconductor substrate 110, which may extend from the second surface 119 to the first surface 117 of the semiconductor substrate 110. Alternatively or additionally, the through electrode 130 may protrude from the first surface 117 of the semiconductor substrate 110 and may extend from a lower surface of the pad insulating layer 120 to an upper surface of the pad insulating layer 120 to penetrate the pad insulating layer 120.

An upper surface of the through electrode 130 may be exposed to the outside. In some embodiments, a horizontal width (or a diameter) of the upper surface of the through electrode 130 may be between about 10 μm to about 100 μm.

The through electrode 130 may include a conductive plug 131 and a conductive barrier layer 133 on an outer surface of the conductive plug 131. The conductive plug 131 may have a shape of a column extending to penetrate the semiconductor substrate 110 and the pad insulating layer 120. The conductive barrier layer 133 may surround a sidewall of the conductive plug 131. The conductive barrier layer 133 may have a cylindrical shape surrounding the sidewall of the conductive plug 131. The conductive barrier layer 133 may extend from a lower end to an upper end of the sidewall of the conductive plug 131, and cover the entire sidewall of the conductive plug 131. For example, the conductive plug 131 may include at least one material, such as, but not limited to, copper (Cu), nickel (Ni), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and ruthenium (Ru). The conductive barrier layer 133 may include at least one material, such as, but not limited to, titanium (Ti), titanium nitride (TiN), tantalum (Ta), tantalum nitride (TaN), tungsten (W), tungsten nitride (WN), ruthenium (Ru), and cobalt (Co). The conductive plug 131 and the conductive barrier layer 133 may be formed by, for example, a physical vapor deposition (PVD) process, a chemical vapor deposition (CVD) process), and/or an electroplating process. The through electrode 130 may be formed by using a via-first process and/or a via-middle process.

A via insulating film 135 may be between the through electrode 130 and the semiconductor substrate 110. The via insulating film 135 may surround the sidewall of the through electrode 130. The via insulating film 135 may include an oxide. For example, the via insulating film 135 may include ozone/tetra-ethyl ortho-silicate (O₃/TEOS)-based high-aspect-ratio process (HARP) oxide formed by a low-pressure CVD (sub-atmospheric CVD) process.

The bonding pad 140 may cover an upper surface of the through electrode 130 and cover a portion of the upper surface of the pad insulating layer 120, which may be adjacent to the upper surface of the through electrode 130. For example, the bonding pad 140 may cover upper surfaces of the upper first insulating layer 121a, the upper second insulating layer 123a, and the upper third insulating layer 124a, and may cover a portion of an upper surface of the buffer layer 127. A remaining portion of the upper surface of the pad insulating layer 120 may be covered by the bonding pad insulating layer 145. For example, the bonding pad insulating layer 145 may cover a portion of the upper surface of the buffer layer 127, which may not be covered by the bonding pad 140. The bonding pad insulating layer 145 may surround a sidewall of the bonding pad 140. An upper surface 149 of the bonding pad 140 may be exposed to the outside.

In some embodiments, the bonding pad 140 may have a multi-layered structure including a conductive core layer 141 and a conductive seed layer 143. The conductive seed layer 143 may be formed to partially cover a surface of the conductive core layer 141. For example, the conductive seed layer 143 may cover portions of the surface of the conductive core layer 141 except for an upper surface of the conductive core layer 141. In some embodiments, the conductive core layer 141 may be formed by performing an electroplating process using the conductive seed layer 143 as a seed. However, the present disclosure is not limited in this regard, and the bonding pad 140 may be formed through various processes other than an electroplating process.

For example, the conductive core layer 141 may include at least one material, such as, but not limited to, copper (Cu), nickel (Ni), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and ruthenium (Ru).

For example, the conductive seed layer 143 may include chromium (Cr), tungsten (W), titanium (Ti), copper (Cu), nickel (Ni), aluminum (Al), palladium (Pd), gold (Au), or a combination thereof. In some embodiments, the conductive seed layer 143 may have a structure in which a titanium (Ti) layer, a TiW layer, and a copper (Cu) layer are stacked.

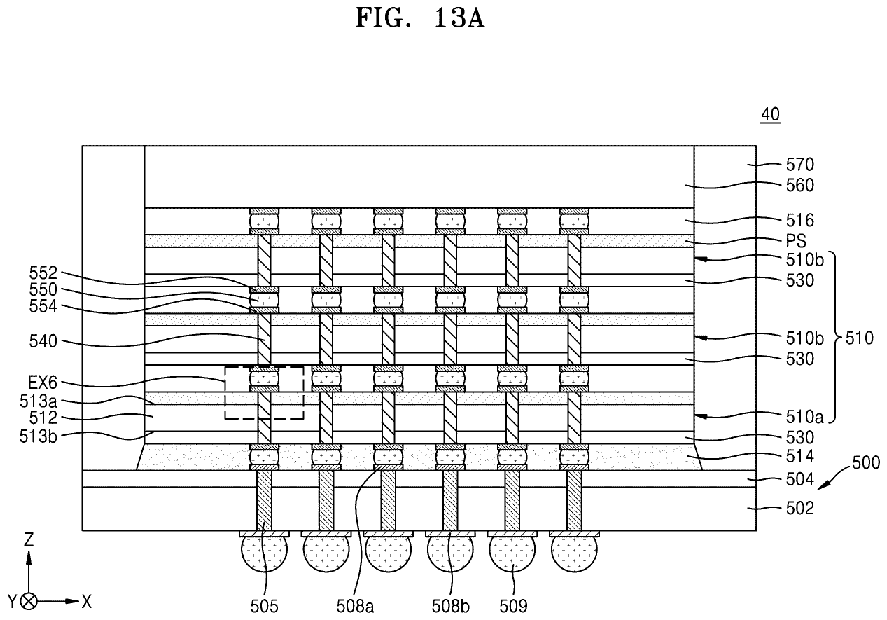

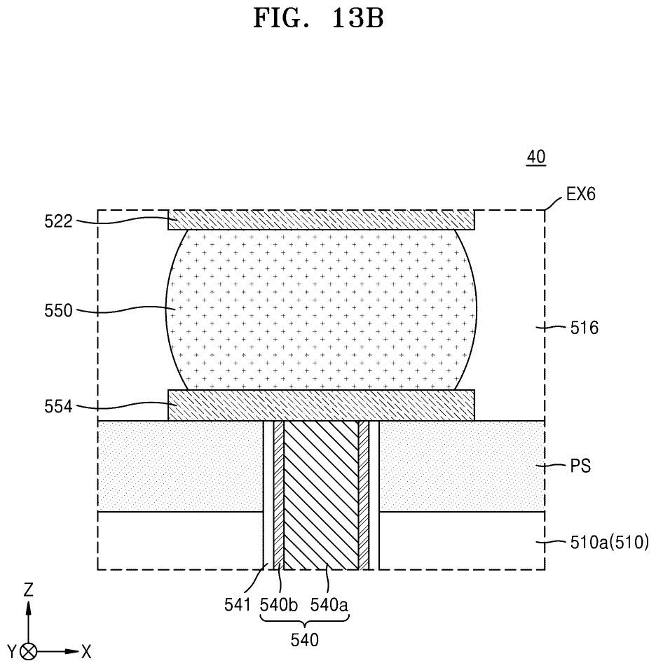

In other embodiments, the bonding pad 140 may have a single-layered structure including a conductive pad. In other embodiments, the bonding pad 140 may also have a multi-layered structure including a conductive pad and an under bump metallurgy (UBM) on the conductive pad. A bonding pad 140 having a different structure from that shown in FIG. 1A is described with reference to FIGS. 13A and 13B.

The conductive pad may include at least one material, such as, but not limited to, chromium (Cr), tungsten (W), titanium (Ti), copper (Cu), nickel (Ni), aluminum (Al), palladium (Pd), and gold (Au). The UBM may include gold (Au), copper (Cu), nickel (Ni), platinum (Pt), tungsten (W), titanium (Ti), chromium (Cr), or a combination thereof.

In some embodiments, the grain size of the conductive plug 131 of the through electrode 130 may be larger than the grain size of the conductive core layer 141 of the bonding pad 140. For example, the grain size of a metal included in the conductive plug 131 may be larger than the particle size of a metal included in the conductive core layer 141. As another example, the conductive plug 131 of the through electrode 130 may be formed by performing heat treatment with a temperature higher than that in formation of the conductive core layer 141 of the bonding pad 140. As another example, the conductive plug 131 of the through electrode 130 may be formed by performing heat treatment with a high temperature of about 300° C., and thus, the metal included in the through electrode 130 may have a relatively large grain size.

In some embodiments, an upper surface of the bonding pad insulating layer 145 may be exposed to the outside and may be substantially coplanar with the upper surface of the bonding pad 140. The upper surface of the bonding pad 140 and the upper surface of the bonding pad insulating layer 145 may form a bonding surface 101 of the semiconductor chip 10.

The wiring structure 150 may be on the second surface 119 of the semiconductor substrate 110. The wiring structure 150 may include a back-end-of-line (BEOL) structure formed on a semiconductor device layer provided on the second surface 119 of the semiconductor substrate 110. The wiring structure 150 may include a wiring insulating layer 151 provided on the second surface 119 of the semiconductor substrate 110, a plurality of wiring lines 153 provided in the wiring insulating layer 151, and a plurality of wiring vias 155. The plurality of wiring lines 153 and the plurality of wiring vias 155 of the wiring structure 150 may be electrically connected to the through electrode 130. In some embodiments, the wiring structure 150 may be electrically connected to individual devices included in the semiconductor device layer.

In some embodiments, the wiring insulating layer 151 may include an oxide and/or a nitride. For example, the wiring insulating layer 151 may include silicon oxide (SiO) and/or silicon nitride (SiN). In some embodiments, the wiring insulating layer 151 may also include an insulating material made of a photoimageable dielectric (PID) material capable of being processed by a photolithography process. For example, the wiring insulating layer 151 may include photosensitive polyimide (PSPI).

The plurality of wiring lines 153 and the plurality of wiring vias 155 may be covered with the wiring insulating layer 151. Each of the plurality of wiring lines 153 may extend in a horizontal direction (e.g., the first horizontal direction X and/or the second horizontal direction Y) within the wiring insulating layer 151. The plurality of wiring lines 153 may be positioned at different levels in the vertical direction Z within the wiring insulating layer 151 to form a multi-layered wiring structure. Each of the plurality of wiring vias 155 may extend in the vertical direction Z within the wiring insulating layer 151. The plurality of wiring vias 155 may extend between the plurality of wiring lines 153 positioned at different vertical levels to electrically connect the plurality of wiring lines 153 positioned at different vertical levels to each other.

For example, each of the plurality of wiring lines 153 and the plurality of wiring vias 155 may include a metal such as, but not limited to, aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), or the like, or alloys thereof.

According to embodiments, the pad insulating layer 120 may include at least one layer of a pad nitride film, at least one layer of a pad oxide film, and a buffer layer that may be distinct from the at least one pad nitride film. Unlike a case where a pad insulating layer does not include at least one layer of a pad nitride film as a comparative example, that is, the case where the pad insulating layer includes one layer of a pad oxide film and a buffer layer, according to embodiments, because the pad insulating layer 120 includes at least one layer of the pad nitride film, thermal resistance of silicon nitride may be lower than thermal resistance of silicon oxide, and thus a semiconductor chip with relatively low thermal resistance and improved heat transfer ability may be provided.

In addition, according to embodiments, because the pad insulating layer 120 includes at least one layer of a pad oxide film that is distinct from at least one layer of the pad nitride film, a minimum thickness to prevent short circuits from occurring may be secured, and thus a semiconductor chip capable of preventing short circuits may be provided.

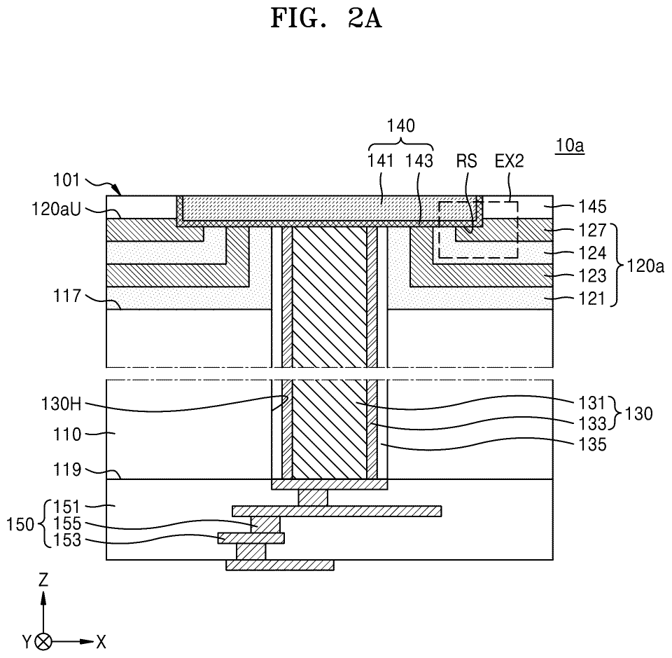

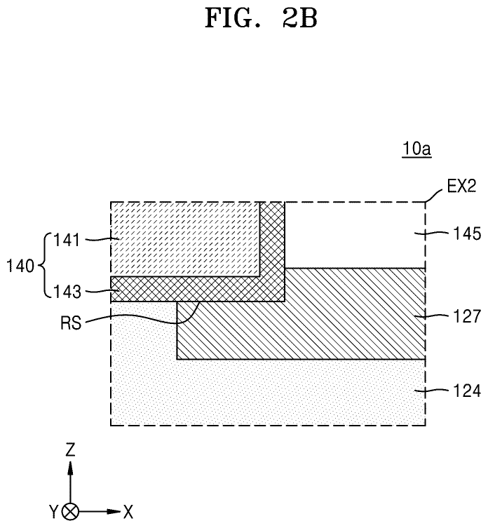

FIG. 2A is a cross-sectional view schematically illustrating a semiconductor chip 10a, according other embodiments. FIG. 2B is an enlarged view illustrating a region indicated as “EX2” in FIG. 2A, according other embodiments. The semiconductor chip 10a of FIGS. 2A and 2B may include and/or may be similar in many respects to the semiconductor chip 10 described above with reference to FIGS. 1A to 1C, and may include additional features not mentioned above. Consequently, repeated descriptions of the semiconductor chip 10a described above with reference to FIGS. 1A to 1C may be omitted for the sake of brevity.

Referring to FIGS. 2A and 2B, the semiconductor chip 10a may include the semiconductor substrate 110, a pad insulating layer 120a, the through electrode 130, the bonding pad 140, and the wiring structure 150.

The pad insulating layer 120a may be provided on the first surface 117 of the semiconductor substrate 110. The pad insulating layer 120a may cover the first surface 117 of the semiconductor substrate 110. Alternatively or additionally, the pad insulating layer 120a may surround a sidewall of the through electrode 130 protruding from the first surface 117 of the semiconductor substrate 110. The pad insulating layer 120a may include a material substantially similar to and/or the same material as that described in the pad insulating layer 120 of FIG. 1A.

In some embodiments, the pad insulating layer 120a may include a plurality of insulating layers 121 to 124 and the buffer layer 127, which may be sequentially stacked on the first surface 117 of the semiconductor substrate 110. The plurality of insulating layers 121 to 124 and the buffer layer 127 may include materials substantially similar to that described in the plurality of insulating layers 121 to 124 and the buffer layer 127 of FIG. 1A.

In some embodiments, the pad insulating layer 120a may include a recess RS. A portion of the pad insulating layer 120a may be exposed through a sidewall and a bottom of the recess RS of the pad insulating layer 120a. For example, a portion of the buffer layer 127 may be exposed through the sidewall of the recess RS, and a portion of the buffer layer 127 and a portion of each of the first insulating layer 121, the second insulating layer 123, and the third insulating layer 124 may be exposed through the bottom of the recess RS. In some embodiments, the recess RS may overlap a portion of the first insulating layer 121, the second insulating layer 123, the third insulating layer 124, and the buffer layer 127 in the vertical direction Z, and may overlap a portion of the buffer layer 127 in the first horizontal direction X and the second horizontal direction Y. A vertical level of the bottom of the recess RS may be lower than a vertical level of an upper surface 120aU of the pad insulating layer 120a. That is, a separation distance from the first surface 117 of the semiconductor substrate 110 to the bottom of the recess RS may be less than a separation distance from the first surface 117 of the semiconductor substrate 110 to the upper surface 120aU of the pad insulating layer 120a.

The bonding pad 140 may be disposed on the recess RS. The bonding pad 140 may cover the sidewall and the bottom of the recess RS. That is, the bonding pad 140 may cover a portion of the buffer layer 127, which may be exposed to the sidewall of the recess RS, and a portion of each of the first insulating layer 121, the second insulating layer 123, and the third insulating layer 124, which may be exposed to the bottom of the recess RS. A portion of a sidewall of the bonding pad 140 may be surrounded by the buffer layer 127. A remaining portion of the sidewall of the bonding pad 140 may be surrounded by the bonding pad insulating layer 145. An upper surface of the bonding pad 140 may be exposed to the outside.

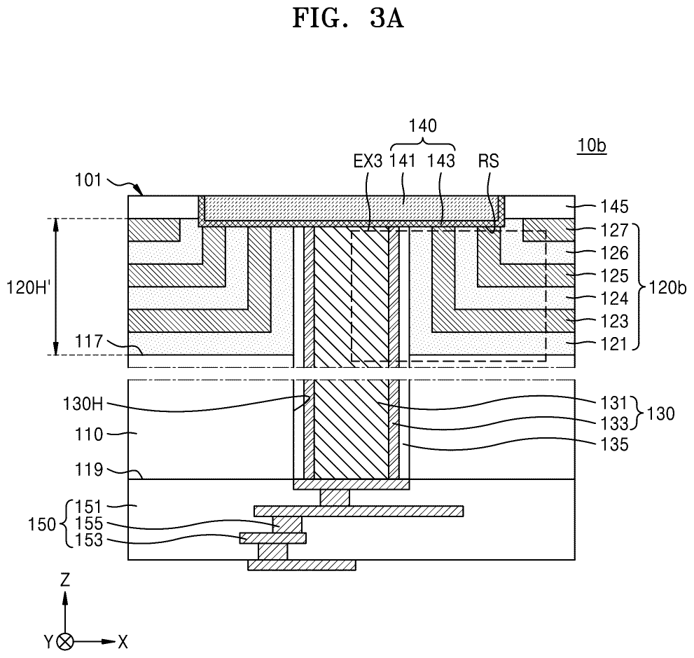

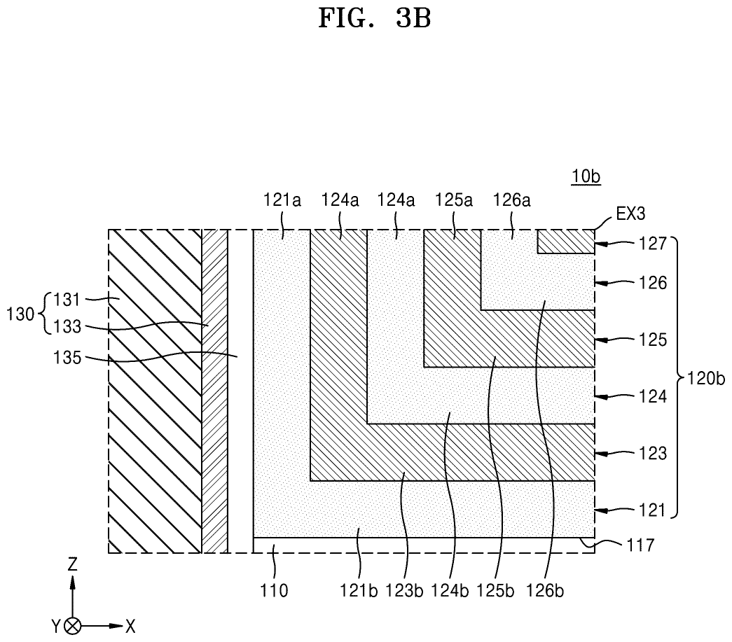

FIG. 3A is a cross-sectional view schematically illustrating a semiconductor chip 10b according to other embodiments. FIG. 3B is an enlarged view illustrating a region indicated as “EX3” in FIG. 3A. The semiconductor chip 10b of FIGS. 3A and 3B may include and/or may be similar in many respects to the semiconductor chip 10 described above with reference to FIGS. 1A to 1C, and may include additional features not mentioned above. Consequently, repeated descriptions of the semiconductor chip 10b described above with reference to FIGS. 1A to 1C may be omitted for the sake of brevity.

Referring to FIGS. 3A and 3B, the semiconductor chip 10b may include the semiconductor substrate 110, a pad insulating layer 120b, the through electrode 130, the bonding pad 140, and the wiring structure 150.

The pad insulating layer 120b may be provided on the first surface 117 of the semiconductor substrate 110. The pad insulating layer 120b may cover the first surface 117 of the semiconductor substrate 110. Alternatively or additionally, the pad insulating layer 120b may surround a sidewall of the through electrode 130 protruding from the first surface 117 of the semiconductor substrate 110. The pad insulating layer 120b may include a material substantially similar to that described in the pad insulating layer 120 of FIG. 1A.

In some embodiments, the pad insulating layer 120b may include a plurality of insulating layers (e.g., the first insulating layer 121, the second insulating layer 123, the third insulating layer 124, a fourth insulating layer 125, and a fifth insulating layer 126) and the buffer layer 127, which may be sequentially stacked on the first surface 117 of the semiconductor substrate 110.

Among the plurality of insulating layers 121 to 126 included in the pad insulating layer 120b, constituent materials of a pair of adjacent insulating layers may be different from each other. For example, the constituent materials of the first insulating layer 121 and the second insulating layer 123 may be different from each other, and the constituent materials of the second insulating layer 123 and the third insulating layer 124 may be different from each other. In some embodiments, the first insulating layer 121 may include silicon oxide (SiO), the second insulating layer 123 may include silicon nitride (SiN), the third insulating layer 124 may include silicon oxide (SiO), the fourth insulating layer 125 may include silicon nitride (SiN), and the fifth insulating layer 126 may include silicon oxide (SiO). For example, the silicon oxide may include SiO₂, and the silicon nitride may include SiN. The buffer layer 127 may include a material having an etch selectivity to the bonding pad insulating layer 145 on the buffer layer 127. For example, the buffer layer 127 may include silicon nitride (SiN).

In some embodiments, the pad insulating layer 120b may include a recess RS. A portion of the pad insulating layer 120b may be exposed through a sidewall and a bottom of the recess RS of the pad insulating layer 120b. As the recess RS may be substantially similar to the recess RS of FIGS. 2A and 2B, detailed description thereof may be omitted.

In some embodiments, a thickness 120H′ of the pad insulating layer 120b in the vertical direction Z may be greater than a thickness of the pad insulating layer 120 described with reference to FIGS. 1A, 1B, and 1C in the vertical direction Z.

In some embodiments, as shown in FIG. 3B, the first insulating layer 121 may include an upper first insulating layer 121a and a lower first insulating layer 121b. The second insulating layer 123 may include an upper second insulating layer 123a and a lower second insulating layer 123b. The third insulating layer 124 may include an upper third insulating layer 124a and a lower third insulating layer 124b. The fourth insulating layer 125 may include an upper fourth insulating layer 125a and a lower fourth insulating layer 125b. The fifth insulating layer 126 may include an upper fifth insulating layer 126a and a lower fifth insulating layer 126b. In some embodiments, the upper first insulating layer 121a, the upper second insulating layer 123a, the upper third insulating layer 124a, the upper fourth insulating layer 125a, and the upper fifth insulating layer 126a may each have a cylindrical shape surrounding a portion of the through electrode 130. In some embodiments, the lower first insulating layer 121b may extend in the first horizontal direction X and the second horizontal direction Y to cover the first surface 117 of the semiconductor substrate 110. The lower second insulating layer 123b may extend in the first horizontal direction X and the second horizontal direction Y to cover an upper surface of the lower first insulating layer 121b. The lower third insulating layer 124b may extend in the first horizontal direction X and the second horizontal direction Y to cover an upper surface of the lower second insulating layer 123b. The lower fourth insulating layer 125b may extend in the first horizontal direction X and the second horizontal direction Y to cover an upper surface of the lower third insulating layer 124b. The lower fifth insulating layer 126b may extend in the first horizontal direction X and the second horizontal direction Y to cover an upper surface of the lower fourth insulating layer 125b.

In some embodiments, the buffer layer 127 may be spaced apart from the sidewall of the through electrode 130 with the upper first insulating layer 121a, the upper second insulating layer 123a, the upper third insulating layer 124a, the upper fourth insulating layer 125a, and the upper fifth insulating layer 126a therebetween. In addition, the buffer layer 127 may be spaced apart from the first surface 117 of the semiconductor substrate 110 with the lower first insulating layer 121b, the lower second insulating layer 123b, the lower third insulating layer 124b, the lower fourth insulating layer 125b, and the lower fifth insulating layer 126b therebetween.

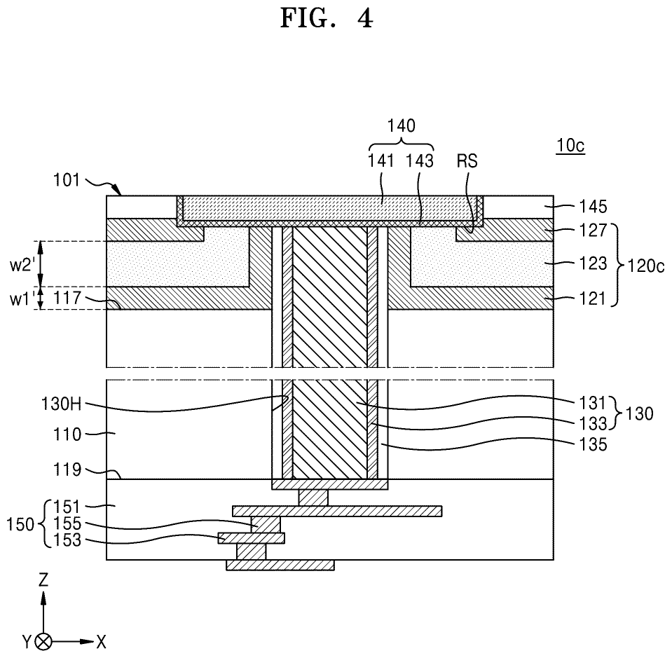

FIG. 4 is a cross-sectional view schematically illustrating a semiconductor chip 10c according to other embodiments. The semiconductor chip 10c of FIG. 4 may include and/or may be similar in many respects to the semiconductor chip 10 described above with reference to FIGS. 1A to 1C, and may include additional features not mentioned above. Consequently, repeated descriptions of the semiconductor chip 10c described above with reference to FIGS. 1A to 1C may be omitted for the sake of brevity.

Referring to FIG. 4, the semiconductor chip 10c may include the semiconductor substrate 110, a pad insulating layer 120c, the through electrode 130, the bonding pad 140, and the wiring structure 150.

The pad insulating layer 120c may be provided on the first surface 117 of the semiconductor substrate 110. The pad insulating layer 120c may cover the first surface 117 of the semiconductor substrate 110. Alternatively or additionally, the pad insulating layer 120c may surround a sidewall of the through electrode 130 protruding from the first surface 117 of the semiconductor substrate 110. The pad insulating layer 120c may include a material substantially similar to that described in the pad insulating layer 120 of FIG. 1A.

In some embodiments, the pad insulating layer 120c may include a plurality of insulating layers (e.g., the first and second insulating layers 121 and 123) and the buffer layer 127, which may be sequentially stacked on the first surface 117 of the semiconductor substrate 110. The number of insulating layers that may be included in the pad insulating layer 120c is not limited thereto and may include an even number of insulating layers of two (2) or more. For example, the pad insulating layer 120c may include the first insulating layer 121 and the second insulating layer 123 as shown in FIG. 4, however, the present disclosure is not limited thereto, and the pad insulating layer 120c may also include a third insulating layer, and a fourth insulating layer.

Among the plurality of insulating layers 121 and 123 included in the pad insulating layer 120c, constituent materials of a pair of adjacent insulating layers may be different from each other. For example, the constituent materials of the first insulating layer 121 and the second insulating layer 123 may be different from each other. In some embodiments, the first insulating layer 121 may include silicon nitride (SiN), and the second insulating layer 123 may include silicon oxide (SiN). The buffer layer 127 may include a material having an etch selectivity to the bonding pad insulating layer 145 on the buffer layer 127. For example, the buffer layer 127 may include silicon nitride (SiN).

That is, the pad insulating layer 120c may include at least one layer of a pad nitride film and at least one layer of a pad oxide film, which may be sequentially and alternately stacked on the semiconductor substrate 110. For example, a pad nitride film may be stacked on the semiconductor substrate 110, and a pad oxide film may be stacked on the pad nitride film.

In some embodiments, the pad insulating layer 120c may include a recess RS. A portion of the pad insulating layer 120c may be exposed through a sidewall and a bottom of the recess RS of the pad insulating layer 120c. As the recess RS may be substantially similar to the recess RS of FIGS. 2A and 2B, detailed description thereof may be omitted.

In some embodiments, a thickness of a pad oxide film may be within a range of about 2500 Å to about 3500 Å, and a thickness of a pad nitride film may be within a range of about 1500 Å to about 2500 Å. In some embodiments, a thickness of the second insulating layer 123 may be greater than a thickness of the first insulating layer 121 and a thickness of the buffer layer 127. In some embodiments, a thickness w1′ of the first insulating layer 121 (or a distance between inner and outer peripheries of the upper first insulating layer 121a) may be within a range of about 1500 Å to about 2500 Å. A thickness w2′ of the second insulating layer 123 (or a distance between inner and outer peripheries of the upper second insulating layer 123a) may be within a range of about 2500 Å to about 3500 Å or about 4500 Å to about 5500 Å.

Accordingly, structural embodiments in which the through electrode 130 is formed through a via-first process or a via-middle process have been described above. Hereinafter, a structural embodiment in which a through electrode is formed through a via-last process is described.

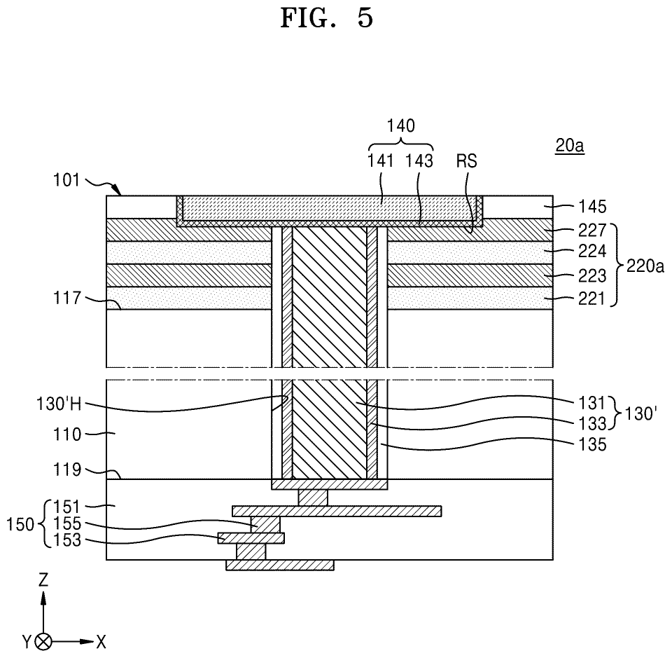

FIG. 5 is a cross-sectional view schematically illustrating a semiconductor chip 20a according to other embodiments. The semiconductor chip 20a of FIG. 5 may include and/or may be similar in many respects to the semiconductor chip 10 described above with reference to FIGS. 1A to 1C, and may include additional features not mentioned above. Consequently, repeated descriptions of the semiconductor chip 20a described above with reference to FIGS. 1A to 1C may be omitted for the sake of brevity.

Referring to FIG. 5, the semiconductor chip 20a may include the semiconductor substrate 110, a pad insulating layer 220a, a through electrode 130′, the bonding pad 140, and the wiring structure 150.

The pad insulating layer 220a may be provided on the first surface 117 of the semiconductor substrate 110. The pad insulating layer 220a may cover the first surface 117 of the semiconductor substrate 110. Alternatively or additionally, the pad insulating layer 220a may surround a sidewall of the through electrode 130′ protruding from the first surface 117 of the semiconductor substrate 110. The pad insulating layer 220a may include a material substantially similar to that described in the pad insulating layer 120 of FIG. 1A.

In some embodiments, the pad insulating layer 220a may include a plurality of insulating layers (e.g., a first insulating layer 221, a second insulating layer 223, and a third insulating layer 224) and a buffer layer 227, which may be sequentially stacked on the first surface 117 of the semiconductor substrate 110. The number of insulating layers 221 to 224 that may be included in the pad insulating layer 220a is not limited thereto and may include an odd number of insulating layers of three (3) or more.

Among the plurality of insulating layers 221 to 224, included in the pad insulating layer 220a, constituent materials of a pair of adjacent insulating layers may be different from each other. For example, the constituent materials of the first insulating layer 221 and the second insulating layer 223 may be different from each other, and the constituent materials of the second insulating layer 223 and the third insulating layer 224 may be different from each other. In some embodiments, the first insulating layer 221 may include silicon oxide (SiO), the second insulating layer 223 may include silicon nitride (SiN), and the third insulating layer 224 may include silicon oxide (SiO). For example, the silicon oxide may include SiO₂, and the silicon nitride may include SiN. The buffer layer 227 may include a material having an etch selectivity to the bonding pad insulating layer 145 on the buffer layer 227. For example, the buffer layer 227 may include silicon nitride. In some embodiments, the thicknesses of the second insulating layer 223 and the buffer layer 227 may be relatively less than the thicknesses of the first insulating layer 221 and the third insulating layer 224.

That is, the pad insulating layer 220a may include at least one layer of a pad oxide film and at least one layer of a pad nitride film, which may be alternately stacked on the semiconductor substrate 110. For example, after a pad oxide film is stacked on the semiconductor substrate 110, a pad nitride film may be stacked on the pad oxide film, and then a pad oxide film may be stacked again.

In some embodiments, the pad insulating layer 220a may include a recess RS. A portion of the pad insulating layer 220a may be exposed through a sidewall and a bottom of the recess RS of the pad insulating layer 220a. As the recess RS may be substantially similar to the recess RS of FIGS. 2A and 2B, a detailed description thereof may be omitted.

In some embodiments, the first insulating layer 221, the second insulating layer 223, the third insulating layer 224, and the buffer layer 227 may extend from the sidewall of the through electrode 130′ in the first horizontal direction X and the second horizontal direction Y. The first insulating layer 221, the second insulating layer 223, the third insulating layer 224, and the buffer layer 227 may be in contact with the sidewall of the through electrode 130′.

The through electrode 130′ may penetrate the semiconductor substrate 110 and the pad insulating layer 220a. The through electrode 130′ may be provided in a through hole 130H′ of the semiconductor substrate 110, which may extend from the second surface 119 to the first surface 117 of the semiconductor substrate 110. In addition, the through electrode 130′ may protrude from the first surface 117 of the semiconductor substrate 110 and may extend from a lower surface of the pad insulating layer 220a to an upper surface of the pad insulating layer 220a to penetrate the pad insulating layer 220a. The through electrode 130′ may be configured generally similarly to the through electrode 130 described with reference to FIG. 1A, but may be formed through a via-last process.

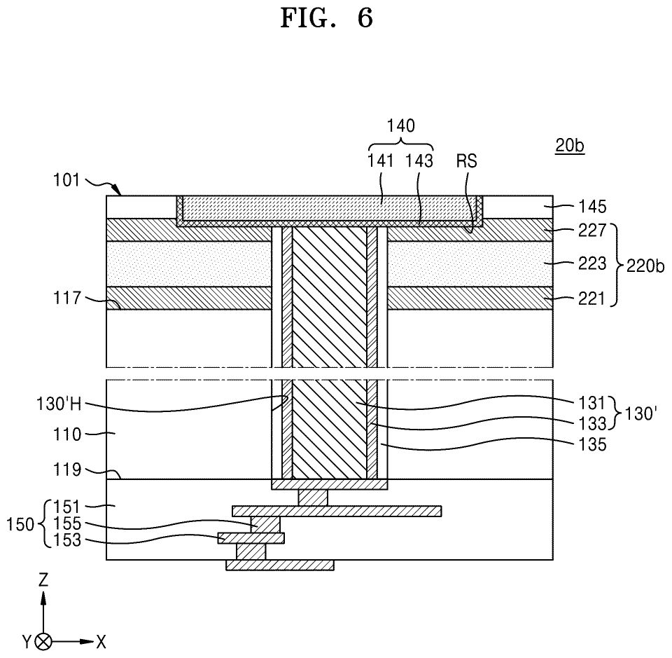

FIG. 6 is a cross-sectional view schematically illustrating a semiconductor chip 20b according to other embodiments. The semiconductor chip 20b of FIG. 6 may include and/or may be similar in many respects to the semiconductor chip 10 described above with reference to FIGS. 1A to 1C, and may include additional features not mentioned above. Consequently, repeated descriptions of the semiconductor chip 20b described above with reference to FIGS. 1A to 1C may be omitted for the sake of brevity.

Referring to FIG. 6, the semiconductor chip 20a may include the semiconductor substrate 110, a pad insulating layer 220b, the through electrode 130′, the bonding pad 140, and the wiring structure 150.

The pad insulating layer 220b may be provided on the first surface 117 of the semiconductor substrate 110. The pad insulating layer 220b may cover the first surface 117 of the semiconductor substrate 110. Alternatively or additionally, the pad insulating layer 220b may surround a sidewall of the through electrode 130′ protruding from the first surface 117 of the semiconductor substrate 110. The pad insulating layer 220b may include a material substantially similar to that described in the pad insulating layer 120 of FIG. 1A.

In some embodiments, the pad insulating layer 220b may include a plurality of insulating layers 221 and 223 (e.g., the first and second insulating layers 221 and 223) and the buffer layer 227, which may be sequentially stacked on the first surface 117 of the semiconductor substrate 110. The number of insulating layers that may be included in the pad insulating layer 220b is not limited thereto and may include an even number of insulating layers of two (2) or more.

For example, the pad insulating layer 220b may include the first insulating layer 221 and the second insulating layer 223 as shown in FIG. 6, however, the present disclosure is not limited thereto, and the pad insulating layer 220b may also include a third insulating layer and a fourth insulating layer.

Among the plurality of insulating layers 221 and 223 included in the pad insulating layer 220b, constituent materials of a pair of adjacent insulating layers may be different from each other. For example, the constituent materials of the first insulating layer 221 and the second insulating layer 223 may be different from each other. In some embodiments, the first insulating layer 221 may include silicon nitride (SiN), and the second insulating layer 223 may include silicon oxide (SiO). The buffer layer 227 may include a material having an etch selectivity to the bonding pad insulating layer 145 on the buffer layer 227. For example, the buffer layer 227 may include silicon nitride (SiN). In some embodiments, a thickness of the second insulating layer 223 may be relatively greater than a thickness of the first insulating layer 221 and a thickness of the buffer layer 227.

That is, the pad insulating layer 220b may include at least one layer of a pad nitride film and at least one layer of a pad oxide film, which are sequentially and alternately stacked on the semiconductor substrate 110. For example, a pad nitride film may be stacked on the semiconductor substrate 110, and a pad oxide film may be stacked on the pad nitride film.

In some embodiments, the pad insulating layer 220b may include a recess RS. A portion of the pad insulating layer 220b may be exposed through a sidewall and a bottom of the recess RS of the pad insulating layer 220b. As the recess RS may be substantially similar to the recess RS of FIGS. 2A and 2B, a detailed description thereof may be omitted.

In some embodiments, the first insulating layer 221, the second insulating layer 223, and the buffer layer 227 may extend from the sidewall of the through electrode 130′ in the first horizontal direction X and the second horizontal direction Y. The first insulating layer 221, the second insulating layer 223, and the buffer layer 227 may be in contact with the sidewall of the through electrode 130′.

The through electrode 130′ may penetrate the semiconductor substrate 110 and the pad insulating layer 220b. The through electrode 130′ may be provided in a through hole 130′H of the semiconductor substrate 110, which may extend from the second surface 119 to the first surface 117 of the semiconductor substrate 110. In addition, the through electrode 130′ may protrude from the first surface 117 of the semiconductor substrate 110 and may extend from a lower surface of the pad insulating layer 220b to an upper surface of the pad insulating layer 220b to penetrate the pad insulating layer 220b. The through electrode 130′ may be configured generally similarly to the through electrode 130 described with reference to FIG. 1A, but may be formed through a via-last process.

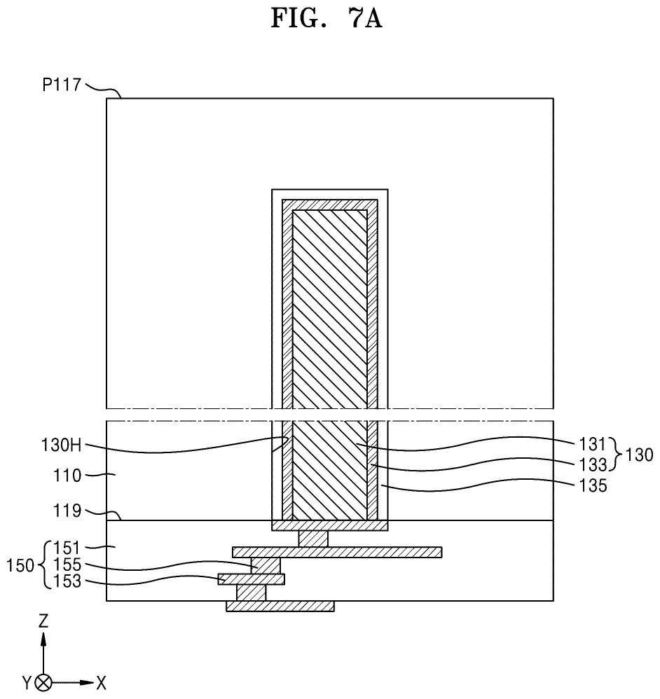

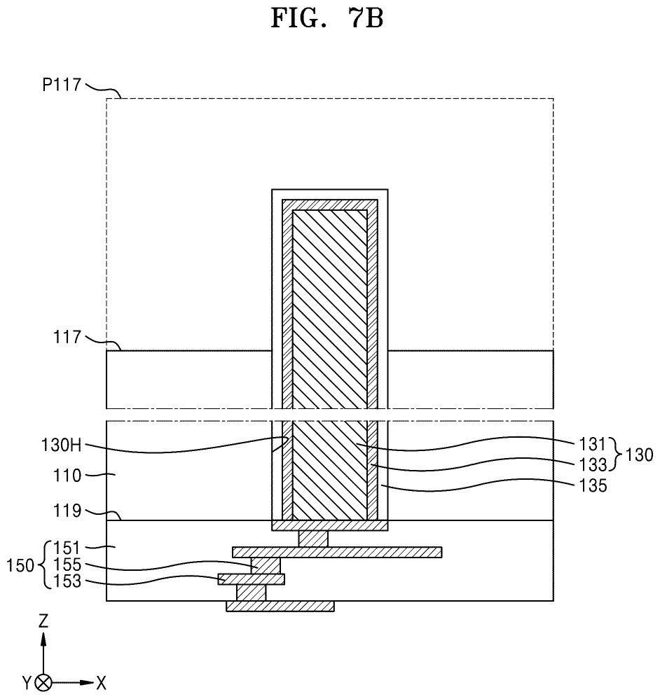

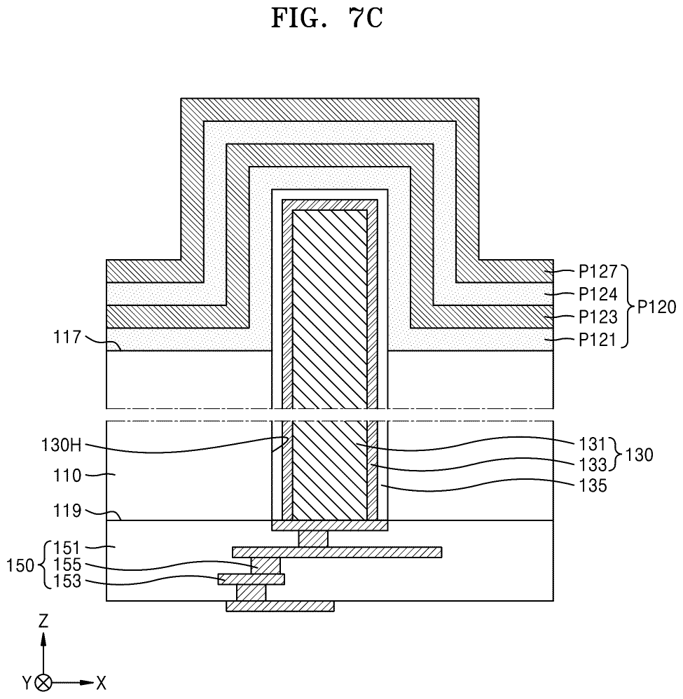

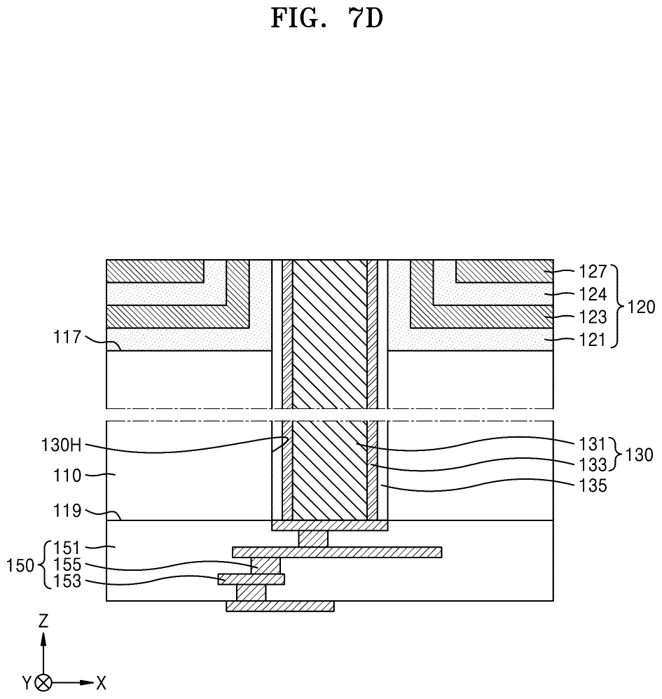

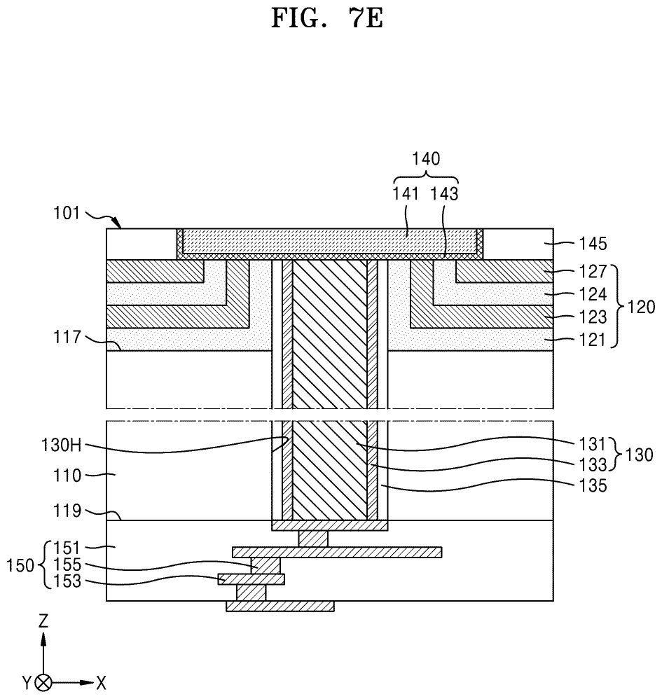

FIGS. 7A to 7E are diagrams illustrating a method of manufacturing a semiconductor chip, according to embodiments in a process order.

Hereinafter, the method of manufacturing the semiconductor chip 10 illustrated in FIGS. 1A, 1B, and 1C is described with reference to FIGS. 7A to 7E.

Referring to FIG. 7A, the semiconductor substrate 110 including a first surface P117 and the second surface 119, which are opposite to each other, is prepared. The semiconductor substrate 110 may be, for example, a semiconductor wafer. Then, a through hole 130H partially penetrating the semiconductor substrate 110 is formed. The through hole 130H may extend from the second surface 119 of the semiconductor substrate 110 toward the first surface P117 thereof. After forming the through hole 130H in the semiconductor substrate 110, a via insulating film 135, the conductive barrier layer 133, and the conductive plug 131 may be sequentially formed on a sidewall of the semiconductor substrate 110, which may define the through hole 130H of the semiconductor substrate 110. The conductive barrier layer 133 and the conductive plug 131 may form the through electrode 130. After forming the via insulating film 135 and the through electrode 130, the wiring structure 150 may be formed on the second surface 119 of the semiconductor substrate 110. The wiring structure 150 may be formed by using, for example, a damascene process.

Referring to FIG. 7B, a portion of the semiconductor substrate 110 may be removed to expose a portion of the through electrode 130. As a result of removing the portion of the semiconductor substrate 110, the through electrode 130 may have a shape penetrating the semiconductor substrate 110 and may protrude from the first surface 117 of the semiconductor substrate 110. To expose the through electrode 130, the portion of the semiconductor substrate 110 may be removed by using a chemical mechanical polishing (CMP) process, an etch-back process, or a combination thereof.

Referring to FIG. 7C, the pad insulating layer 120 may be formed on the first surface 117 of the semiconductor substrate 110. In some embodiments, a preliminary first insulating layer P121, a preliminary second insulating layer P123, and a preliminary third insulating layer P124 may be sequentially formed on the first surface 117 of the semiconductor substrate 110. The preliminary first insulating layer P121 may be formed to cover the first surface 117 of the semiconductor substrate 110 and a portion of the through electrode 130 protruding from the first surface 117 of the semiconductor substrate 110. The preliminary second insulating layer P123 may be formed to cover the preliminary first insulating layer P121, and the preliminary third insulating layer P124 may be formed to cover the preliminary second insulating layer P123. In some embodiments, the preliminary first insulating layer P121 and the preliminary third insulating layer P124 may include silicon oxide (SiO), and the preliminary second insulating layer P123 may include silicon nitride (SiN). After the preliminary first insulating layer P121, the preliminary second insulating layer P123, and the preliminary third insulating layer P124 are sequentially formed, a preliminary buffer layer P127 may be formed on the preliminary third insulating layer P124. The preliminary buffer layer P127 may be formed to cover the preliminary third insulating layer P124.

Referring to FIG. 7D, after the pad insulating layer 120 is formed, a polishing process may be performed on a resultant product of FIG. 7C to expose the through electrode 130. For example, a portion of the pad insulating layer 120, a portion of the via insulating film 135, a portion of the conductive barrier layer 133, and a portion of the conductive plug 131 may be removed in the polishing process. In some embodiments, the polishing process may include a CMP process.

In some embodiments, the upper surface of the pad insulating layer 120 and the upper surface of the through electrode 130 may be planarized in the polishing process. For example, the upper surface of the pad insulating layer 120 and the upper surface of the through electrode 130 may be substantially coplanar with each other.

Referring to FIG. 7E, a preliminary bonding pad insulating layer for forming the bonding pad insulating layer 145 may be formed on a resultant product of FIG. 7D. The preliminary bonding pad insulating layer may cover the upper surface of the pad insulating layer 120 and the upper surface of the through electrode 130, which may be exposed through the polishing process described in FIG. 7D. Thereafter, to form the bonding pad 140, a portion of the preliminary bonding pad insulating layer may be removed to expose the through electrode 130. The conductive seed layer 143 and the conductive core layer 141 may be formed in a space defined by removing a portion of the preliminary bonding pad insulating layer. The conductive seed layer 143 may be conformally formed along a surface exposed by a space defined by removing a portion of the preliminary bonding pad insulating layer, that is, an exposed surface of the bonding pad insulating layer 145, an exposed surface of the pad insulating layer 120, and an exposed surface of the through electrode 130. The conductive core layer 141 may be formed by, for example, a PVD process such as, but not limited to, sputtering. The conductive core layer 141 may be formed to cover the conductive seed layer 143. The conductive core layer 141 may be formed by performing an electroplating process using the conductive seed layer 143 as a seed. Thereafter, a planarization process may be performed on the conductive core layer 141, the conductive seed layer 143, and the bonding pad insulating layer 145. The planarization process may include a CMP process. In some embodiments, the upper surfaces of the conductive core layer 141, the conductive seed layer 143, and the bonding pad insulating layer 145 may be substantially coplanar with each other. The conductive seed layer 143 and the conductive core layer 141 may form the bonding pad 140.

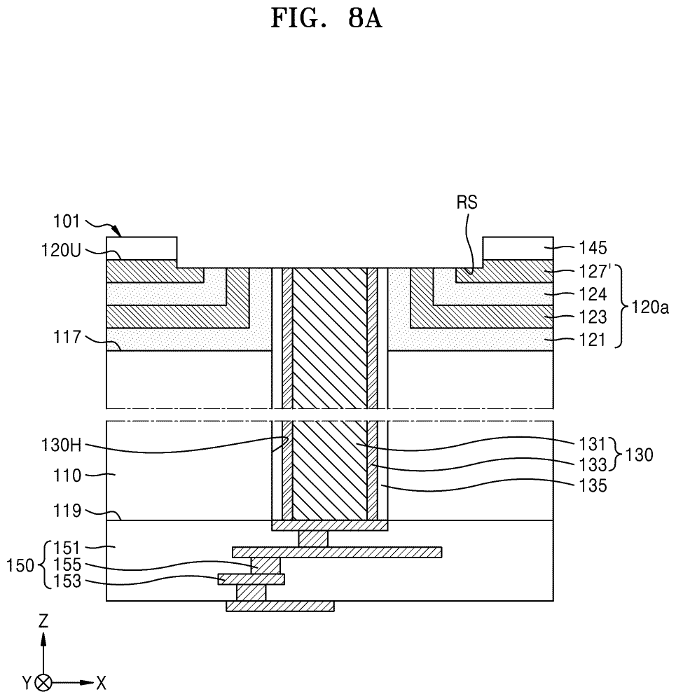

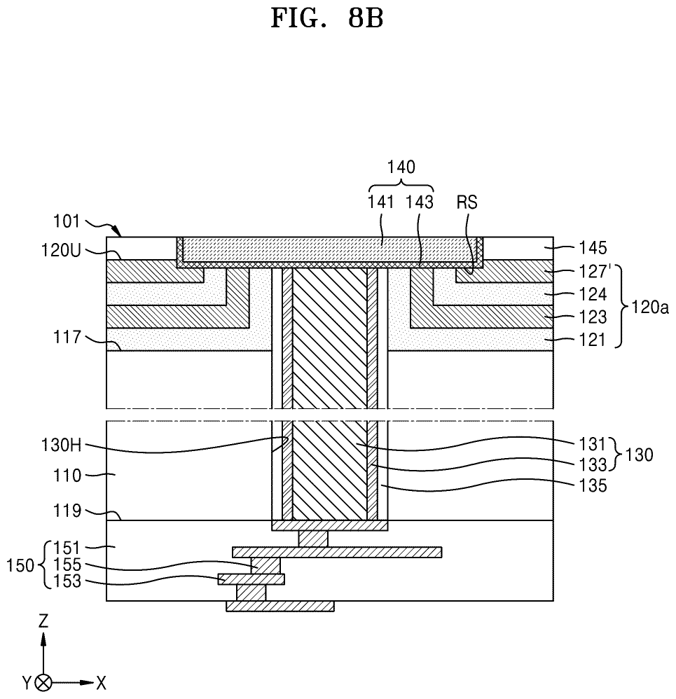

FIGS. 8A and 8B are diagrams illustrating a method of manufacturing a semiconductor chip, according to embodiments in a process order. In particular, FIGS. 8A and 8B are diagrams illustrating an embodiment of a process performed after the manufacturing process described with reference to FIGS. 7A to 7D instead of the manufacturing process described above with reference to FIG. 7E.

Referring to FIG. 8A, a preliminary bonding pad insulating layer for forming the bonding pad insulating layer 145 may be formed on the resultant product of FIG. 7D. The preliminary bonding pad insulating layer may cover the upper surface of the pad insulating layer 120 and the upper surface of the through electrode 130, which may be exposed through the polishing process described in FIG. 7D. Thereafter, to form the bonding pad 140, a portion of the preliminary bonding pad insulating layer may be removed to expose the through electrode 130. Accordingly, the bonding pad insulating layer 145 may be formed. In a process of removing a portion of the preliminary bonding pad insulating layer, a portion of an upper portion of the through electrode 130 and a portion of the pad insulating layer 120, which may be exposed by removing a portion of the preliminary bonding pad insulating layer, may be removed. The plurality of insulating layers 121 to 124 and the buffer layer 127 included in the pad insulating layer 120 may be partially removed, and the recess RS may be formed. The buffer layer 127 may serve as an end of point of etching for securing that the through electrode 130 is exposed.

Referring to FIG. 8B, the conductive seed layer 143 and the conductive core layer 141 may be formed on the recess RS. The conductive seed layer 143 may be conformally formed along a surface exposed by the recess RS, that is, an exposed surface of the pad insulating layer 120, an exposed surface of the through electrode 130, and an exposed surface of the bonding pad insulating layer 145. The conductive core layer 141 may be formed by, for example, a PVD process such as, but not limited to, sputtering. The conductive core layer 141 may be formed to cover the conductive seed layer 143. The conductive core layer 141 may be formed by performing an electroplating process using the conductive seed layer 143 as a seed. Thereafter, a planarization process may be performed on the conductive core layer 141, the conductive seed layer 143, and the bonding pad insulating layer 145. The planarization process may include a CMP process. The conductive seed layer 143 and the conductive core layer 141 may form the bonding pad 140.

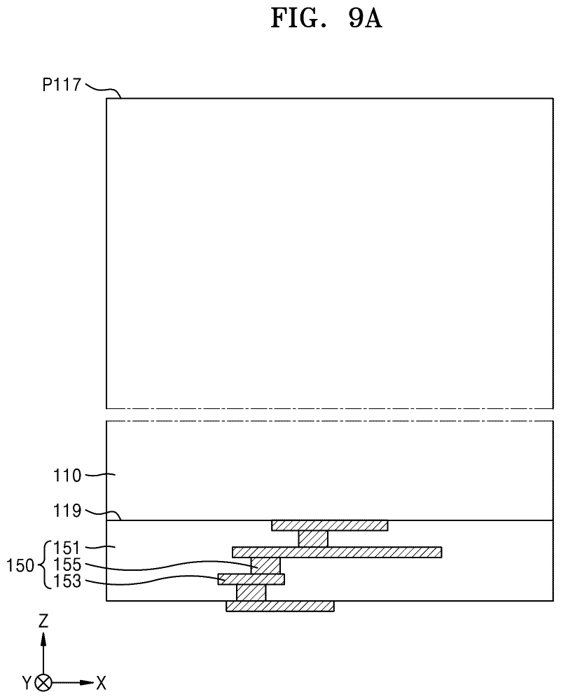

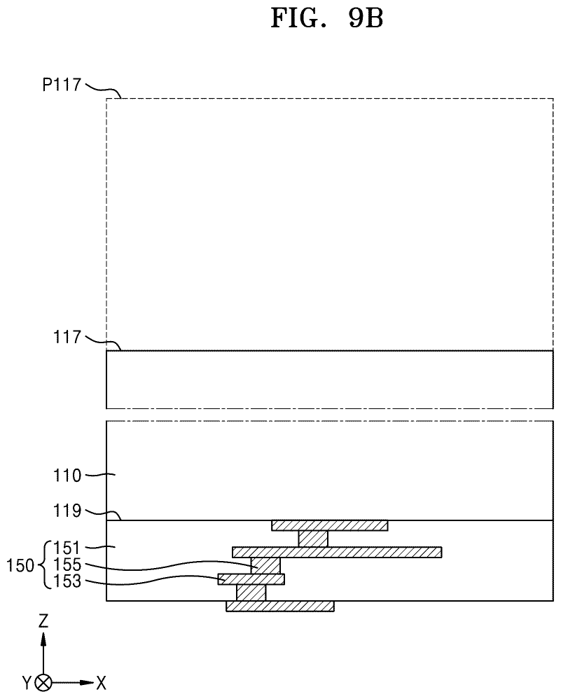

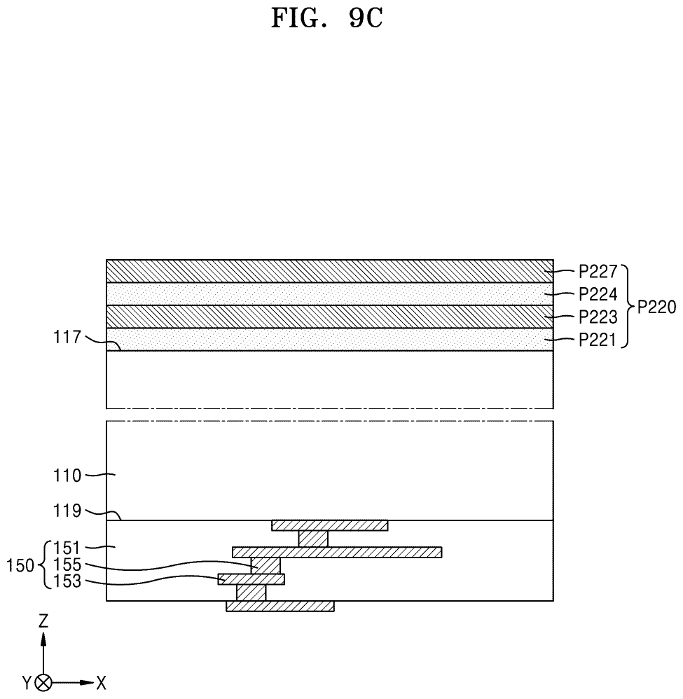

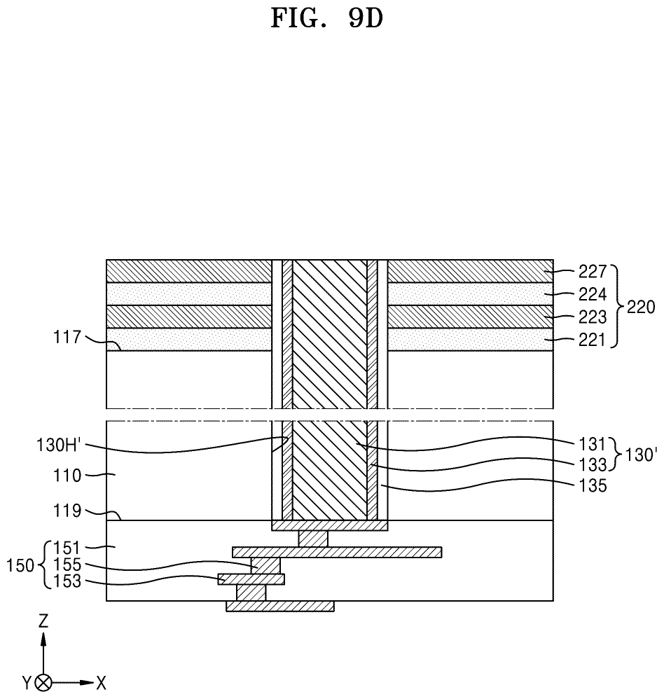

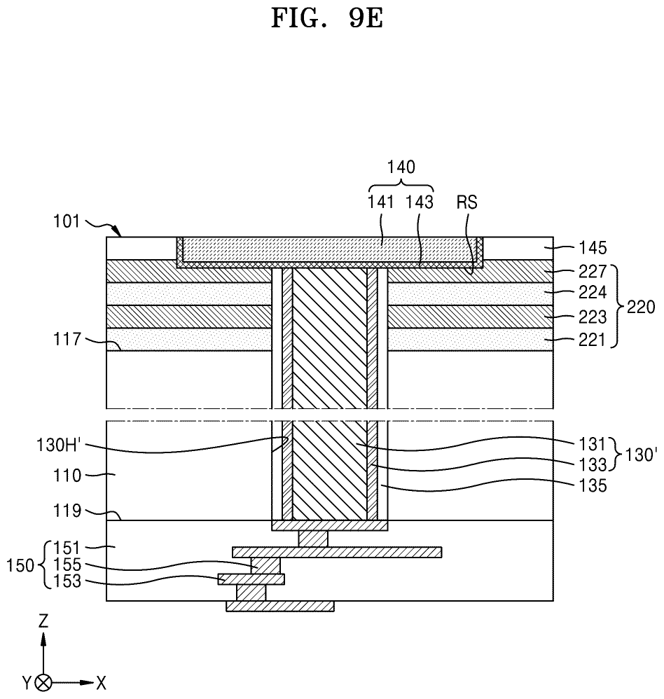

FIGS. 9A to 9E are diagrams illustrating a method of manufacturing a semiconductor chip, according to embodiments in a process order.

Referring to FIG. 9A, the semiconductor substrate 110 including a first surface P117 and the second surface 119, which may be opposite to each other, is prepared. The semiconductor substrate 110 may be, for example, a semiconductor wafer. Thereafter, the wiring structure 150 may be formed on the second surface 119 of the semiconductor substrate 110. The wiring structure 150 may be formed using, for example, a damascene process.

Referring to FIG. 9B, a portion of the semiconductor substrate 110 may be removed to reduce a thickness of the semiconductor substrate 110. To remove a portion of the semiconductor substrate 110, a portion of the semiconductor substrate 110 may be removed by using a CMP process, an etch-back process, or a combination thereof.

Referring to FIG. 9C, a preliminary pad insulating layer P220 may be formed on the first surface 117 of the semiconductor substrate 110. In some embodiments, a preliminary first insulating layer P221, a preliminary second insulating layer P223, and a preliminary third insulating layer P224 may be sequentially formed on the first surface 117 of the semiconductor substrate 110. The preliminary first insulating layer P221 may be formed to cover the first surface 117 of the semiconductor substrate 110 and a portion of the through electrode 130′ protruding from the first surface 117 of the semiconductor substrate 110. The preliminary second insulating layer P223 may be formed to cover the preliminary first insulating layer P221, and the preliminary third insulating layer P224 may be formed to cover the preliminary second insulating layer P223. In some embodiments, the preliminary first insulating layer P221 and the preliminary third insulating layer P224 may include silicon oxide (SiO), and the preliminary second insulating layer P223 may include silicon nitride (SiN). After the preliminary first insulating layer P221, the preliminary second insulating layer P223 and the preliminary third insulating layer P224 are sequentially formed, a preliminary buffer layer P227 may be formed on the preliminary third insulating layer P224. The preliminary buffer layer P227 may be formed to cover the preliminary third insulating layer P224.

Referring to FIG. 9D, a through hole 130H′ penetrating the preliminary first insulating layer P221, the preliminary second insulating layer P223 the preliminary third insulating layer P224, the preliminary buffer layer P227, and the semiconductor substrate 110 may be formed on a resultant product of FIG. 9C. To form the through hole 130H′, a portion of each of the preliminary first insulating layer P221, the preliminary second insulating layer P223, the preliminary third insulating layer P224, and the preliminary buffer layer P227 may be removed, and the first insulating layer 221, the second insulating layer 223, the third insulating layer 224, and the buffer layer 227 may be formed. To form the through hole 130H′, the semiconductor substrate 110 may be etched so that the wiring structure 150 may be exposed, and the wiring structure 150 may be exposed through a bottom of the through hole 130H′.

Thereafter, the via insulating film 135, the conductive barrier layer 133, and the conductive plug 131 may be sequentially formed on a sidewall of the through hole 130H′ such that the via insulating film 135, the conductive barrier layer 133, and the conductive plug 131 conformally extend on the sidewall of the through hole 130H′. Thereafter, upper surfaces of the via insulating film 135, the conductive barrier layer 133, and the conductive plug 131 and an upper surface of the buffer layer 227 may be planarized. The planarization process may include a CMP process. The conductive barrier layer 133 and the conductive plug 131 may form the through electrode 130′. The through electrode 130′ may be in contact with the wiring structure 150 to be electrically and physically connected to the wiring structure 150.

Referring to FIG. 9E, a preliminary bonding pad insulating layer for forming the bonding pad insulating layer 145 may be formed. The preliminary bonding pad insulating layer may cover an upper surface of the pad insulating layer 120 and an upper surface of the through electrode 130′. Thereafter, to form the bonding pad 140, a portion of the preliminary bonding pad insulating layer may be removed to expose the through electrode 130′. Accordingly, the bonding pad insulating layer 145 may be formed. In a process of removing a portion of the preliminary bonding pad insulating layer, a portion of an upper portion of the through electrode 130′ and a portion of the buffer layer 227, which is exposed by removing a portion of the preliminary bonding pad insulating layer, may be removed, and the recess RS may be formed. The buffer layer 227 may serve as an end of point of etching for securing that the through electrode 130′ is exposed.

Thereafter, the conductive seed layer 143 and the conductive core layer 141 may be formed on the recess RS. The conductive seed layer 143 may be conformally formed along a surface exposed by the recess RS, that is, an exposed surface of the pad insulating layer 120, an exposed surface of the through electrode 130′, and an exposed surface of the bonding pad insulating layer 145. The conductive core layer 141 may be formed by, for example, a PVD process such as sputtering. The conductive core layer 141 may be formed to cover the conductive seed layer 143. The conductive core layer 141 may be formed by performing an electroplating process using the conductive seed layer 143 as a seed. Thereafter, a planarization process may be performed on the conductive core layer 141, the conductive seed layer 143, and the bonding pad insulating layer 145. The planarization process may include a CMP process. The conductive seed layer 143 and the conductive core layer 141 may form the bonding pad 140.

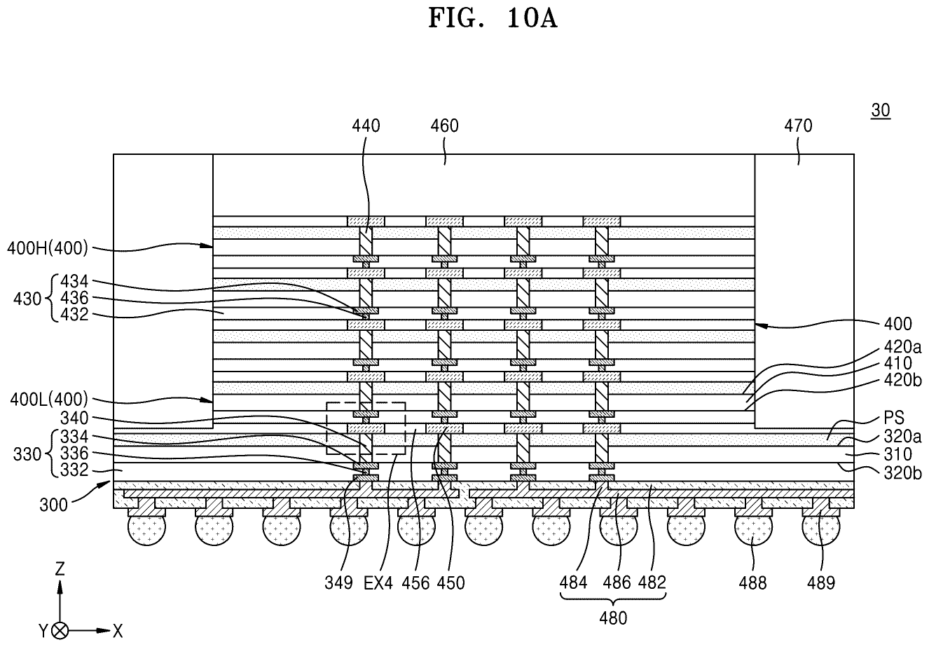

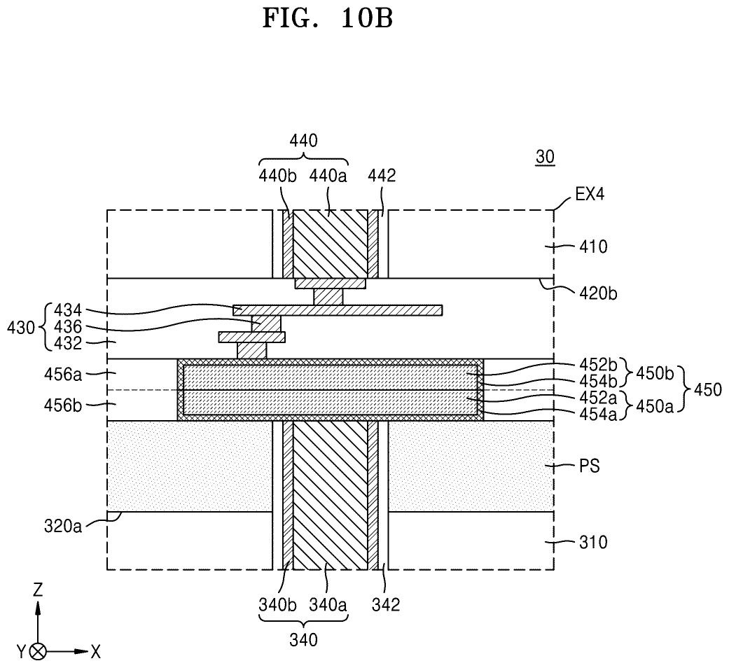

FIG. 10A is a cross-sectional view illustrating a semiconductor package 30, according to embodiments. FIG. 10B is an enlarged view illustrating a region indicated as “EX4” in FIG. 10A, according to embodiments.

Referring to FIGS. 10A and 10B, the semiconductor package 30 may include a first semiconductor chip 300 and a plurality of second semiconductor chips 400. FIG. 10A illustrates that the semiconductor package 30 includes four (4) second semiconductor chips 400, however, the present disclosure is not limited thereto. For example, the semiconductor package 30 may include two (2) or more second semiconductor chips 400. In some embodiments, the semiconductor package 30 may include a number of second semiconductor chips 400, wherein the number is a multiple of four (4).

The plurality of second semiconductor chips 400 may be sequentially stacked on the first semiconductor chip 300. Herein, for convenience of explanation, among the plurality of second semiconductor chips 400, a second semiconductor chip 400 positioned on the first semiconductor chip 300 may be defined as a lowermost second semiconductor chip 400L, and a second semiconductor chip positioned at the uppermost end may be defined as an uppermost second semiconductor chip 400H.

The first semiconductor chip 300 may include a first semiconductor substrate 310 having a second surface 320b and a first surface 320a, which may be opposite to each other, a first individual device disposed on the second surface 320b of the first semiconductor substrate 310, a first wiring structure 330 disposed on the second surface 320b of the first semiconductor substrate 310, and a plurality of first through electrodes 340 connected to the first wiring structure 330 and penetrating the first semiconductor substrate 310. The first wiring structure 330 may include a first wiring layer 332, a first wiring via 336, and a first wiring line 334.

The first semiconductor chip 300 may further include a plurality of chip pads 349 disposed on a lower surface of the first semiconductor chip 300 and electrically connected to the first wiring structure 330. The plurality of chip pads 349 may be electrically connected to the first wiring line 334 and/or the first wiring via 336, and may be electrically connected to the first individual device through the first wiring line 334 and/or the first wiring via 336.

In the semiconductor chip 10, the first semiconductor chip 300 may be arranged such that the second surface 320b of the first semiconductor substrate 310 faces downward and the first surface 320a thereof faces upward.

The second semiconductor chip 400 may include a second semiconductor substrate 410 having a second surface 420b and a first surface 420a, which may be opposite to each other, a second individual device disposed on the second surface 420b of the second semiconductor substrate 410, a second wiring structure 430 disposed on the second surface 420b of the second semiconductor substrate 410, and a plurality of second through electrodes 440 connected to the second wiring structure 430 and penetrating the second semiconductor substrate 410. The second wiring structure 430 may include a second wiring layer 432, a second wiring line 434 and/or a second wiring via 436.

In the semiconductor chip 10, the second semiconductor chip 400 may be arranged such that the second surface 420b of the second semiconductor substrate 410 faces downward and the first surface 420a thereof faces upward. That is, the second semiconductor chip 400 may be arranged such that the second surface 420b of the second semiconductor substrate 410 faces the first surface 420a of the first semiconductor chip 300.

The first semiconductor substrate 310 and the second semiconductor substrate 410 may include and/or may be similar in many respects to the semiconductor substrate 110 shown in FIG. 1A. The first wiring structure 330 and the second wiring structure 430 may include and/or may be similar in many respects to the wiring structure 150 shown in FIG. 1A, the first wiring layer 332 and the second wiring layer 432 may include and/or may be similar in many respects to the wiring insulating layer 151 shown in FIG. 1A, the first wiring line 334 and the second wiring line 434 may include and/or may be similar in many respects to the wiring line 153 shown in FIG. 1A, and the first wiring via 336 and the second wiring via 436 may include and/or may be similar in many respects to the wiring via 155 shown in FIG. 1A. The first through electrode 340 and the second through electrode 440 may include and/or may be similar in many respects to the through electrode 130 shown in FIGS. 1A, 1B, 1C, 2A, 3A, 3B, and 4 or the through electrode 130′ shown in FIGS. 5 and 6.

Each of the first individual device and the second individual device may include various types of individual devices. The individual devices may include various microelectronic devices, for example, a metal-oxide-semiconductor field effect transistor (MOSFET) such as a complementary metal-oxide-semiconductor (CMOS) transistor, an image sensor such as a system large scale integration (LSI) and CMOS imaging sensor (CIS), a micro-electro-mechanical system (MEMS), an active device, a passive device, and the like. Each of the first individual device and the second individual device may further include a conductive wiring and/or a conductive plug.

The first semiconductor chip 300 and/or the second semiconductor chip 400 may be a memory semiconductor chip. In some embodiments, the first semiconductor chip 300 may include a serial-parallel conversion circuit and may be a buffer chip for controlling the plurality of second semiconductor chips 400. Alternatively or additionally, the plurality of second semiconductor chips 400 may be and/or may include memory chips including memory cells. For example, the first semiconductor chip 300 and the plurality of second semiconductor chips 400 may be high bandwidth memory (HBM) chips, the first semiconductor chip 300 may be referred to as an HBM controller die, and each of the plurality of second semiconductor chips 400 may be referred to as a dynamic random access memory (DRAM) die.

The first wiring structure 330 may include the first wiring layer 332, a plurality of first wiring vias 336 penetrating a portion of the first wiring layer 332, and a plurality of first wiring lines 334 connected to the plurality of first wiring vias 336. The second wiring structure 430 may include the second wiring layer 432, a plurality of second wiring vias 436 penetrating a portion of the second wiring layer 432, and a plurality of second wiring lines 434 connected to the plurality of second wiring vias 436.

In some embodiments, each of the first through electrode 340 and the second through electrode 440 may include a through silicon via (TSV). The first through electrode 340 may include a conductive plug 340a penetrating the first semiconductor substrate 310 and a conductive barrier film 340b surrounding the conductive plug 340a. The second through electrode 440 may include a conductive plug 440a penetrating the second semiconductor substrate 410 and a conductive barrier film 440b surrounding the conductive plug 440a. A via insulating film 342 may be between the first through electrode 340 and the first semiconductor substrate 310 to surround a sidewall of the first through electrode 340, and a via insulating film 442 may be between the second through electrode 440 and the second semiconductor substrate 410 to surround a sidewall of the second through electrode 440. Each of the first through electrode 340 and the second through electrode 440 may be formed by using any one of a via-first process, a via-middle process, and a via-last process.

The first semiconductor chip 300 may be electrically connected to each of the plurality of second semiconductor chips 400 through a bonding structure 450 to exchange signals and/or to provide power and ground. The bonding structure 450 may be between the first semiconductor chip 300 and the lowermost second semiconductor chip 400L and between the plurality of second semiconductor chips 400, which may be adjacent to each other. A bonding insulating layer 456 may be between the first semiconductor chip 300 and the lowermost second semiconductor chip 400L and the plurality of second semiconductor chips 400, which may be adjacent to each other, and may be arranged to surround the bonding structure 450. The bonding structure 450 may be surrounded by the bonding insulating layer 456 in a plan view.

The bonding structure 450 may be between the second wiring via 436 and/or the second wiring line 434 of the second wiring structure 430 and the first through electrode 340 and between the second wiring via 436 and/or the second wiring line 434 of the second wiring structure 430 and the second through electrode 440. The bonding structure 450 may electrically connect the second wiring via 436 and/or the second wiring line 434 of the second wiring structure 430 to the first through electrode 340, and may electrically connect the second wiring via 436 and/or the second wiring line 434 of the second wiring structure 430 to the second through electrode 440. The bonding structure 450 may electrically connect the first through electrode 340 to the second through electrode 440 positioned in the lowermost second semiconductor chip 400L, and may electrically connect the second through electrode 440 within any one second semiconductor chip 400 of the plurality of second semiconductor chips 400 to corresponding second through electrode 440 of another one of the plurality of second semiconductor chips 400.

The bonding structure 450 may be a structure in which a plurality of bonding pads (e.g., a first bonding pad 450a and a second bonding pad 450b) may be bonded to each other by using a direct bonding method. For example, the plurality of bonding pads 450a and 450b may be expanded by heat to come into contact with each other. Alternatively or additionally, the plurality of bonding pads 450a and 450b may be integrated with each other through diffusion bonding in which metal atoms in the plurality of bonding pads 450a and 450b diffuse, and accordingly the bonding structure 450 may be formed.

The first bonding pad 450a may include a first conductive core layer 452a and a first conductive seed layer 454a, and the second bonding pad 450b may include a second conductive core layer 452b and a second conductive seed layer 454b. Each of the plurality of bonding pads 450a and 450b may include and/or may be similar in many respects to the bonding pad 140 shown in FIG. 1A. Each of the first conductive core layer 452a and the second conductive core layer 452b may include and/or may be similar in many respects to the conductive core layer 141 shown in FIG. 1A, and each of the first conductive seed layer 454a and the second conductive seed layer 454b may include and/or may be similar in many respects to the conductive seed layer 143 shown in FIG. 1A.

On the first surface 320a of the first semiconductor substrate 310, a protective insulating structure PS may be arranged between the bonding structure 450 and the first semiconductor substrate 310, or on the second surface 420b of the second semiconductor substrate 410, the protective insulating structure PS may be arranged between the bonding structure 450 and the second semiconductor substrate 410. The protective insulating structure PS may be one of the pad insulating layers 120, 120a, 120b, 120c, 220a, and 220b described with reference to FIGS. 1A, 1B, 1C, 2A, 2B, 3A, 3B, 4, 5, and 6. In particular, when the first through electrode 340 and the second through electrode 440 are formed by either a via-first process or a via-middle process, the protective insulating structure PS may be one of the pad insulating layers 120, 120a, 120b, and 120c described with reference to FIGS. 1A, 1B, 1C, 2A, 2B, 3A, 3B, and 4, and when the first through electrode 340 and the second through electrode 440 are formed by a via-last process, the protective insulating structure PS may be one of the pad insulating layers 220a and 220b described with reference to FIGS. 5 and 6.

The semiconductor package 30 may further include a dummy support substrate 460 disposed on the uppermost second semiconductor chip 400H. The dummy support substrate 460 may include, for example, a semiconductor material such as silicon (Si). In some embodiments, the dummy support substrate 460 may include only a semiconductor material. For example, the dummy support substrate 460 may be part of a bare wafer.

The semiconductor package 30 may further include a molding layer 470 disposed on the first semiconductor chip 300 and covering side surfaces of the plurality of second semiconductor chips 400. The molding layer 470 may cover a portion of an upper surface of the first semiconductor chip 300, which may not be covered with the plurality of second semiconductor chips 400. In some embodiments, the molding layer 470 may not cover an upper surface of the uppermost second semiconductor chip 400H. In some embodiments, the molding layer 470 may also be formed to further cover the upper surface of the uppermost second semiconductor chip 400H among the plurality of second semiconductor chips 400. The molding layer 470 may include, for example, an epoxy mold compound (EMC).

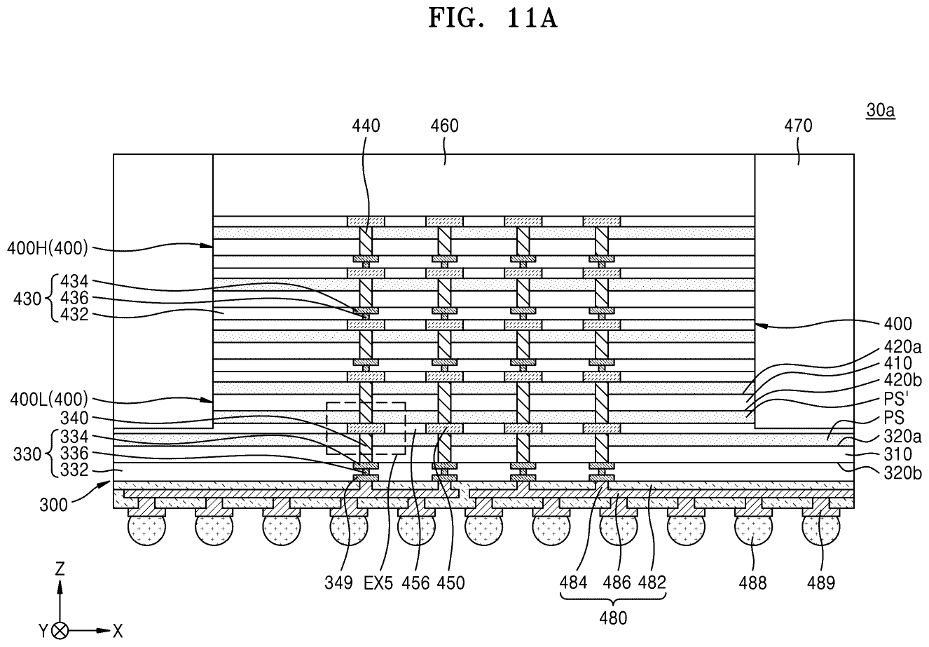

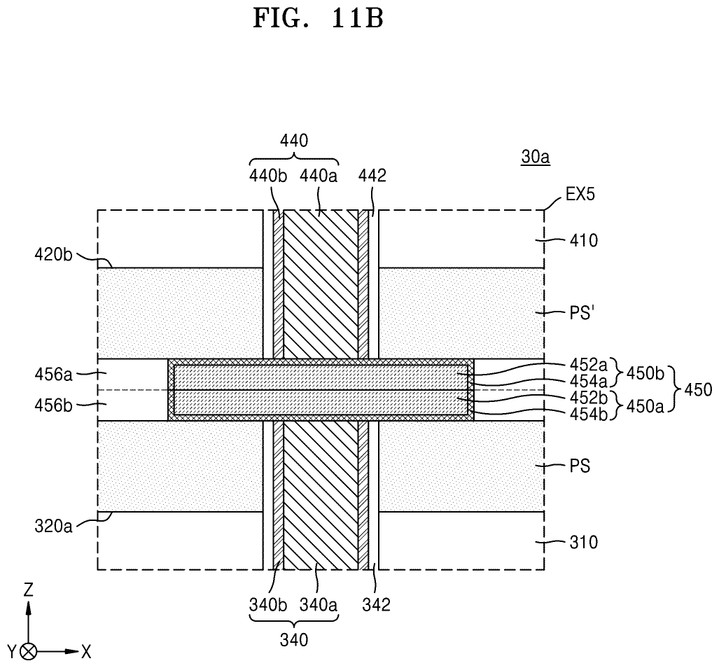

FIG. 11A is a cross-sectional view illustrating a semiconductor package 30a, according to embodiments. FIG. 11B is an enlarged view illustrating a region indicated as “EX5” in FIG. 11A, according to embodiments. The semiconductor package 30a of FIGS. 11A and 11B may include and/or may be similar in many respects to the semiconductor package 30 described above with reference to FIGS. 10A and 10B, and may include additional features not mentioned above. Consequently, repeated descriptions of the semiconductor package 30a described above with reference to FIGS. 10A and 10B may be omitted for the sake of brevity.

The bonding structure 450 may be a structure in which a plurality of bonding pads (e.g., a first bonding pad 450a and a second bonding pad 450b) may be bonded to each other by using a direct bonding method. For example, the plurality of bonding pads 450a and 450b may be expanded by heat to come into contact with each other. Alternatively or additionally, the plurality of bonding pads 450a and 450b may be integrated with each other through diffusion bonding in which metal atoms in the plurality of bonding pads 450a and 450b diffuse, and accordingly, the bonding structure 450 may be formed.

The first bonding pad 450a may include a first conductive core layer 452a and a first conductive seed layer 454a, and the second bonding pad 450b may include a second conductive core layer 452b and a second conductive seed layer 454b.

On the first surface 320a of the first semiconductor substrate 310, a first protective insulating structure PS may be arranged between the bonding structure 450 and the first semiconductor substrate 310, and on the first surface 420a of the second semiconductor substrate 410, the first protective insulating structure PS may be between the bonding structure 450 and the second semiconductor substrate 410. In addition, on the second surface 420b of the second semiconductor substrate 410, a second protective insulating structure PS may be arranged between the bonding structure 450 and the second semiconductor substrate 410. The protective insulating structure PS may be one of the pad insulating layers 120, 120a, 120b, 120c, 220a, and 220b described with reference to FIGS. 1A, 1B, 1C, 2A, 2B, 3A, 3B, 4, 5, and 6. In particular, when the first through electrode 340 and the second through electrode 440 are formed by either a via-first process or a via-middle process, the protective insulating structure PS may be one of the pad insulating layers 120, 120a, 120b, and 120c described with reference to FIGS. 1A, 1B, 1C, 2A, 2B, 3A, 3B, and 4, and when the first through electrode 340 and the second through electrode 440 are formed by a via-last process, the protective insulating structure PS may be one of the pad insulating layers 220a and 220b described with reference to FIGS. 5 and 6.

In an embodiment, on the first surface 420a of the second semiconductor substrate 410, the second protective insulating structure PS' may be arranged between the bonding structure 450 and the second semiconductor substrate 410. The second protective insulating structure PS' may be configured in a substantially similar manner to the protective insulating structure PS described above with reference to FIGS. 5 and 6.

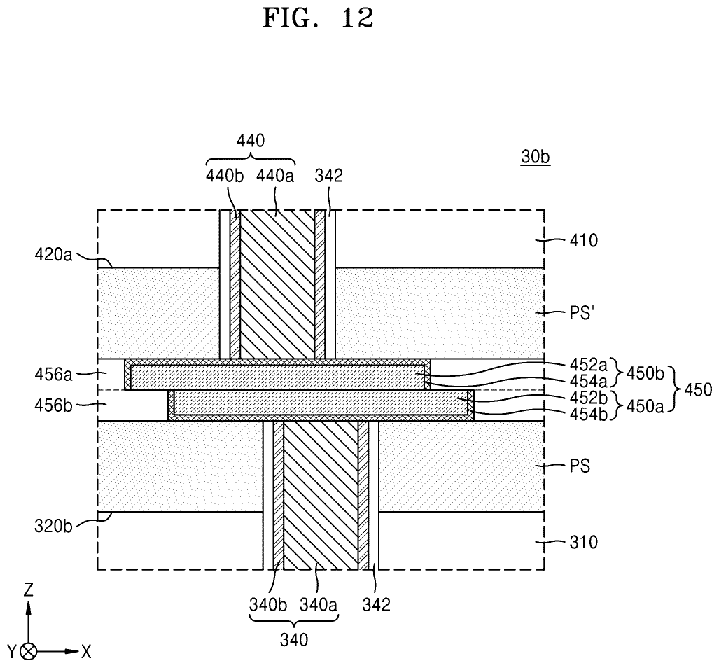

FIG. 12 is a cross-sectional view illustrating a portion of a semiconductor package 30b, according to embodiments. In FIG. 12, a portion of the semiconductor package 30b, which corresponds to the region indicated as “EX5” in FIG. 11, is shown.

Referring to FIG. 12, a center of the first through electrode 340 may be misaligned with a center of the second through electrode 440. That is, a center of an upper surface of the first through electrode 340 and a center of an upper surface of the second through electrode 440 may be spaced apart from each other in a horizontal direction (e.g., the first horizontal direction X and/or the second horizontal direction Y).

Even when the center of the first through electrode 340 is misaligned with the center of the second through electrode 440, the plurality of bonding pads 450a and 450b may be integrated with each other at a portion where the plurality of bonding pads 450a and 450b directly contact each other.

FIG. 13A is a cross-sectional view illustrating a semiconductor package 40, according to embodiments. FIG. 13B is an enlarged view illustrating a region indicated as “EX6” in FIG. 13A.

Referring to FIGS. 13A and 13B, the semiconductor package 40 may include a package substrate 500 and a plurality of semiconductor chips 510 stacked on the package substrate 500. The package substrate 500 may include and/or may be similar in many respects to the semiconductor substrate 110 shown in FIGS. 1A and 1B. In some embodiments, the package substrate 500 may be a printed circuit board (PCB). In some embodiments, the package substrate 500 may be an interposer. The package substrate 500 may include a substrate base 502, an internal wiring structure 504, and an internal through electrode 505 connected to the internal wiring structure 504 and penetrating the substrate base 502.

The substrate base 502 may include at least one material, such as, but not limited to, phenol resin, epoxy resin, and polyimide. For example, the substrate base 502 may include at least one material, such as, but not limited to, frame retardant 4 (FR4), tetrafunctional epoxy, polyphenylene ether, epoxy/polyphenylene oxide, bismaleimide triazine (BT), thermount, cyanate ester, polyimide, and a liquid crystal polymer. The substrate base 502 may generally have a flat plate shape and include an upper surface and a lower surface that are opposite to each other.

The substrate base 502 may be formed in a plurality of layers. For example, the substrate base 502 may include a first substrate base and a second substrate base disposed on a lower surface of the first substrate base. The first substrate base may include an inorganic insulating material. For example, the first substrate base may include at least one of an oxide (e.g., silicon oxide (SiO)) or a nitride (e.g. silicon nitride (SiN)). The second substrate base may include a material different from the material of the first substrate base. For example, the first substrate base may include an inorganic insulating material, and the second substrate base may include an organic insulating material. In some embodiments, the second substrate base may include a PID. In some embodiments, the second substrate base may also include an inorganic insulating material.

An upper conductive pad 508a may be disposed on an upper surface of the internal wiring structure 504. The upper conductive pads 508a may be disposed on the upper surface of the internal wiring structure 504 to be spaced apart from each other in the first horizontal direction X and/or the second horizontal direction Y. For example, the upper conductive pad 508a may include at least one metal, such as, but not limited to, tungsten (W), aluminum (Al), and copper (Cu). The upper conductive pad 508a may be between the internal through electrode 505 and a connection bump 550 to electrically connect between the internal through electrode 505 and the connection bump 550.

A lower conductive pad 508b may be disposed on a lower surface of the substrate base 502. The lower conductive pads 508b may be disposed on the lower surface of the substrate base 502 to be spaced apart from each other in the first horizontal direction X and/or the second horizontal direction Y. For example, the lower conductive pad 508b may include at least one metal, such as, but not limited to, tungsten (W), aluminum (Al), and copper (Cu). The lower conductive pad 508b may be a pad between the internal through electrode 505 and an external connection terminal 509 to electrically connect between the internal through electrode 505 and the external connection terminal 509 configured to connect the semiconductor package 40 and an external device to each other. The external connection terminal 509 may be, for example, a solder ball or a bump.

In some embodiments, the upper conductive pad 508a and the lower conductive pad 508b may be portions of circuit wirings patterned after coating copper (Cu) foils respectively on the upper surface and the lower surface of the substrate base 502, the portions being exposed by resist layers.

In some embodiments, the internal through electrode 505 may include a TSV. In particular, the internal through electrode 505 may include a conductive plug having a column shape penetrating the substrate base 502 and a conductive barrier film having a cylindrical shape surrounding a sidewall of the conductive plug. The conductive plug may include at least one material, such as, but not limited to, copper (Cu), nickel (Ni), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and ruthenium (Ru). The conductive barrier film may include at least one material, such as, but not limited to, titanium (Ti), TiN, tantalum (Ta), TaN, tungsten (W), WN, ruthenium (Ru), and cobalt (Co). In some embodiments, a via insulating film may be between the substrate base 502 and the internal through electrode 505. The via insulating film may include an oxide film, a nitride film, a carbon film, a polymer, or a combination thereof.

The plurality of semiconductor chips 510 may be mounted on the package substrate 500. For example, a first semiconductor chip 510a may be sequentially stacked on the package substrate 500, a second semiconductor chip 510b may be stacked on the first semiconductor chip 510a, and the second semiconductor chip 510b may be stacked again on the second semiconductor chip 510b.

Each of the plurality of semiconductor chips 510 may include a semiconductor substrate 512 having a first surface 513a and a second surface 513b opposite to the first surface 513a, a wiring structure 530 disposed on the second surface 513b of the semiconductor substrate 512, and a plurality of through electrodes 540 connected to the wiring structure 530 and penetrating the semiconductor substrate 512. In the semiconductor package 40, the semiconductor substrate 512 may be arranged such that the first surface 513a thereof faces upward and the second surface 513b thereof faces downward. The semiconductor substrate 512 is a component similar to the semiconductor substrate 110 shown in FIGS. 1A and 1B.

Each of the plurality of semiconductor chips 510 may include various types of individual devices. The individual devices may include various microelectronic devices, for example, a MOSFET such as a CMOS transistor, an image sensor such as a system LSI, a CIS, a MEMS, an active device, a passive device, and the like. Each of the individual devices may further include a conductive wiring or a conductive plug.

Each of the plurality of semiconductor chips 510 may be and/or may include a memory chip, for example, an HBM chip. For example, the first semiconductor chip 510a may include a buffer die that functions as a circuit and the plurality of second semiconductor chip 510b may include a plurality of memory dies sequentially stacked on the first semiconductor chip 510a. The first semiconductor chip 510a may be referred to as an HBM controller die, and each of a plurality of second semiconductor chips 510b may be referred to as a DRAM die. However, the number of memory dies that may be included in the plurality of second semiconductor chip 510b is not limited thereto and may be configured to include one memory die or three (3) or more memory dies.

An underfill layer 514 may be between the package substrate 500 and the first semiconductor chip 510a. The underfill layer 514 may fill a space between the package substrate 500 and the first semiconductor chip 510a and surround a sidewall of each of a plurality of connection bumps 550 between the package substrate 500 and the first semiconductor chip 510a. The underfill layer 514 may include an epoxy resin and an inorganic filler and/or an organic filler contained in the epoxy resin. The underfill layer 514 may be formed by a capillary under-fill process.

An interlayer molding layer 516 may be between the first semiconductor chip 510a and a second semiconductor chip 510b at the lowermost end and between the plurality of second semiconductor chips 510b. The interlayer molding layer 516 may fill a space between the first semiconductor chip 510a and the second semiconductor chip 510b at the lowermost end and surround a sidewall of each of the plurality of connection bumps 550 between the first semiconductor chip 510a and the second semiconductor chip 510b at the lowermost end. For example, the interlayer molding layer 516 may be configured to improve the adhesive strength of each of components and/or to prevent a decrease in physical strength due to transformation of each of components. Alternatively or additionally, for example, the interlayer molding layer 516 may be configured to remove a space where foreign materials or moisture may penetrate and to prevent electrical migration.

For example, the interlayer molding layer 516 may include an epoxy resin and an inorganic filler and/or an organic filler contained in the epoxy resin. In some embodiments, the interlayer molding layer 516 may include an EMC.

Each of the plurality of semiconductor chips 510 may include the wiring structure 530. The wiring structure 530 may include a wiring layer, a plurality of wiring vias penetrating a portion of the wiring layer, and a plurality of wiring lines connected to the plurality of wiring vias. The wiring structure 530 is a component similar to the wiring structure 150 shown in FIG. 1A.

Each of the plurality of semiconductor chips 510 may include a through electrode 540. The plurality of semiconductor chips 510 may be electrically connected to each other by the through electrode 540. The plurality of semiconductor chips 510 may be electrically connected to the package substrate 500 by the through electrode 540. The through electrode 540 may provide at least one of a signal, power, or ground for the plurality of semiconductor chips 510. In some embodiments, the through electrode 540 may include a TSV.

In particular, the through electrode 540 may include a conductive plug having a column shape penetrating the semiconductor substrate 512 and a conductive barrier film having a cylindrical shape surrounding a sidewall of the conductive plug. The conductive plug and the conductive barrier film may include materials similar to that described in the internal through electrode 505 above. In some embodiments, a via insulating film 541 may be between the semiconductor substrate 512 and the through electrode 540. The via insulating film 541 may include an oxide film, a nitride film, a carbide film, a polymer, or a combination thereof. The plurality of through electrodes 540 may be formed by any one of a via-first process, a via-middle process, or a via-last process. The plurality of through electrodes 540 may include and/or may be similar in many respects to the through electrode 130 shown in FIGS. 1A, 1B, 1C, 2A, 3A, 3B, and 4 or the through electrode 130′ shown in FIGS. 5 and 6.

The plurality of semiconductor chips 510 may be electrically connected to each other through the connection bump 550 to exchange signals and provide power and ground. The first semiconductor chip 510a may be electrically and physically connected to the package substrate 500 through the connection bump 550, and the plurality of second semiconductor chips 510b may be electrically and physically connected to the package substrate 500 through the connection bump 550. To electrically and physically connect the plurality of semiconductor chips 510 to each other, a first bonding pad 552 may be provided on the first surface 513a of the semiconductor substrate 512, and a second bonding pad 554 may be provided on the second surface 513b of the semiconductor substrate 512.

The first bonding pad 552 and the second bonding pad 554 may be respectively arranged at positions corresponding to the through electrode 540 to be electrically connected to the through electrode 540, however, the present disclosure is not limited thereto. For example, the first bonding pad 552 and the second bonding pad 554 may be formed at positioned away from the through electrode 540 and may also be electrically connected to the through electrode 540 through a redistribution layer. The first bonding pad 552 and the second bonding pad 554 may be defined by a standard protocol such as a Joint Electron Device Engineering Council (JEDEC) standard, and may each have a thickness of several hundred nanometers to several micrometers. For example, each of the first bonding pad 552 and the second bonding pad 554 may include one or more of aluminum (Al), copper (Cu), tantalum (Ta), titanium (Ti), tungsten (W), nickel (Ni), and gold (Au).

In some embodiments, each of the first bonding pad 552 and the second bonding pad 554 may have a single-layered structure including a conductive pad. In other embodiments, each of the first bonding pad 552 and the second bonding pad 554 may also have a multi-layered structure including a conductive pad and a UBM00 on the conductive pad. In other embodiments, each of the first bonding pad 552 and the second bonding pad 554 may also include a conductive pad, a UBM on the conductive pad, and a conductive seed layer on the UBM. For example, the connection bump 550 may be a component formed by an electroplating process using the conductive seed layer included in the second bonding pad 554 as a seed and a reflow process.

The protective insulating structure PS may be disposed on the first surface 513a of each of a plurality of semiconductor substrates 512. The protective insulating structure PS may be one of the pad insulating layers 120, 120a, 120b, 120c, 220a, and 220b described with reference to FIGS. 1A, 1B, 1C, 2A, 2B, 3A, 3B, 4, 5, and 6. In particular, when the through electrode 540 is formed by either a via-first process or a via-middle process, the protective insulating structure PS may be one of the pad insulating layers 120, 120a, 120b, and 120c described with reference to FIGS. 1A, 1B, 1C, 2A, 2B, 3A, 3B, and 4, and when the through electrode 540 is formed by a via-last process, the protective insulating structure PS may be one of the pad insulating layers 220a and 220b described with reference to FIGS. 5 and 6. In other embodiments, the protective insulating structure PS may be disposed on the second surface 513b of any one semiconductor substrate 512 among the plurality of semiconductor substrates 512 instead of the wiring structure 530, and in such embodiments, the through electrode 540 may penetrate the protective insulating structure PS to be in contact with the second bonding pad 554 disposed on the second surface 513b of the semiconductor substrate 512.

The semiconductor package 40 may further include a dummy support substrate 560 disposed on the second semiconductor chip 510b at an uppermost end. The dummy support substrate 560 may include, for example, a semiconductor material such as silicon (Si). In some embodiments, the dummy support substrate 560 may include only a semiconductor material. For example, the dummy support substrate 560 may be part of a bare wafer.

The semiconductor package 40 may further include a molding layer 570 covering side surfaces of the first semiconductor chip 510a and the plurality of second semiconductor chips 510b. In some embodiments, the molding layer 570 may not cover an upper surface of the second semiconductor chip 510b at the uppermost end. In other embodiments, the molding layer 570 may also be formed to further cover the upper surface of the second semiconductor chip 510b at the uppermost end among the plurality of second semiconductor chips 510b. For example, the molding layer 570 may include an epoxy resin and an inorganic filler and/or an organic filler contained in the epoxy resin. For example, the molding layer 570 may include an EMC.

While the present disclosure has been particularly shown and described with reference to embodiments thereof, it may be understood that various changes in form and details may be made therein without departing from the spirit and scope of the following claims.

What is claimed is:

1. A semiconductor chip, comprising:
a semiconductor substrate;
a pad insulating layer on the semiconductor substrate;
a through electrode at least partially penetrating the semiconductor substrate and the pad insulating layer; and
a bonding pad on an upper portion of the through electrode and electrically and physically coupled with the through electrode,
wherein the pad insulating layer comprises:
a first insulating layer;
a second insulating layer on the first insulating layer; and
a buffer layer on the second insulating layer,
wherein the first insulating layer comprises a first material and the second insulating layer comprises a second material different from the first material.

2. The semiconductor chip of claim 1, wherein the first insulating layer comprises a silicon nitride film, and
wherein the second insulating layer comprises a silicon oxide film.

3. The semiconductor chip of claim 1, wherein the pad insulating layer further comprises a third insulating layer between the second insulating layer and the buffer layer,
wherein the first insulating layer comprises a silicon oxide film,
wherein the second insulating layer comprises a silicon nitride film, and
wherein the third insulating layer comprises another silicon oxide film.

4. The semiconductor chip of claim 1, wherein the bonding pad at least partially overlaps a portion of the buffer layer in a horizontal direction.

5. The semiconductor chip of claim 1, wherein the first insulating layer, the second insulating layer, and the buffer layer are disposed on a lower portion of the bonding pad to be in contact with the bonding pad.

6. The semiconductor chip of claim 1, wherein the first insulating layer comprises:
an upper first insulating layer conformally extending along a sidewall of the through electrode; and
a lower first insulating layer conformally extending along an upper surface of the semiconductor substrate from the upper first insulating layer.

7. The semiconductor chip of claim 6, wherein the upper first insulating layer has a cylindrical shape at least partially surrounding the sidewall of the through electrode.

8. The semiconductor chip of claim 1, wherein each of the first insulating layer, the second insulating layer, and the buffer layer is in contact with a sidewall of the through electrode.

9. The semiconductor chip of claim 1, wherein the buffer layer comprises a silicon nitride film.

10. The semiconductor chip of claim 1, wherein the bonding pad comprises:
a conductive core layer; and
a conductive seed layer disposed between the conductive core layer and the pad insulating layer and extending to at least partially cover a portion of a surface of the conductive core layer.

11. The semiconductor chip of claim 1, wherein the bonding pad comprises at least one of copper or nickel.

12. The semiconductor chip of claim 1, further comprising:
a wiring structure comprising:
a wiring insulating layer disposed on the semiconductor substrate to face the pad insulating layer;
a wiring line; and
a wiring via,
wherein the wiring line and the wiring via are provided in the wiring insulating layer, and
wherein the wiring line and the wiring via are electrically coupled with the through electrode.

13. A semiconductor chip, comprising:
a semiconductor substrate comprising a first surface and a second surface facing the first surface;
a through electrode at least partially penetrating the semiconductor substrate;
a pad insulating layer at least partially surrounding a portion of a sidewall of the through electrode and disposed on the first surface of the semiconductor substrate;
a bonding pad on an upper portion of the through electrode and electrically and physically coupled with the through electrode; and
a wiring structure comprising:
a wiring insulating layer disposed on the second surface of the semiconductor substrate;
a wiring line; and
a wiring via,
wherein the wiring line and the wiring via are provided in the wiring insulating layer,
wherein the wiring line and the wiring via are electrically coupled with the through electrode,
wherein the pad insulating layer comprises:
a first insulating layer;
a second insulating layer on the first insulating layer; and
a buffer layer on the second insulating layer and comprising a silicon nitride film,
wherein the buffer layer is spaced apart from the first insulating layer with the second insulating layer therebetween.

14. The semiconductor chip of claim 13, wherein a second thickness of the second insulating layer is greater than a first thickness of the first insulating layer.

15. The semiconductor chip of claim 13, wherein a thickness of the first insulating layer is within a range of 1500 atom size (Å) to 2500 Å.

16. The semiconductor chip of claim 13, wherein the pad insulating layer further comprises a third insulating layer between the second insulating layer and the buffer layer,
wherein a first thickness of the first insulating layer is greater than a second thickness of the second insulating layer, and
wherein a third thickness of the third insulating layer is greater than the second thickness of the second insulating layer.

17. A semiconductor package, comprising:
a first semiconductor chip; and
a second semiconductor chip bonded to the first semiconductor chip,
wherein the first semiconductor chip comprises:
a first semiconductor substrate comprising a first surface and a second surface opposite to the first surface;
a first protective insulating structure on the first surface of the first semiconductor substrate;
a first through electrode at least partially penetrating the first semiconductor substrate and the first protective insulating structure; and
a first bonding pad on an upper portion of the first through electrode,
wherein the second semiconductor chip comprises a second semiconductor substrate and a second bonding pad in contact with the first bonding pad,
wherein the first protective insulating structure comprises:
a first insulating layer comprising a first material;
a second insulating layer on the first insulating layer and comprising a second material different from the first material; and
a buffer layer on the second insulating layer and comprising a third material different from the second material.

18. The semiconductor package of claim 17, wherein the first insulating layer comprises silicon nitride,
wherein the second insulating layer comprises silicon oxide, and
wherein the buffer layer comprises silicon nitride.

19. The semiconductor package of claim 17, wherein the first protective insulating structure further comprises a third insulating layer between the second insulating layer and the buffer layer,
wherein the first insulating layer comprises silicon oxide,
wherein the second insulating layer comprises silicon nitride,
wherein the third insulating layer comprises silicon oxide, and
wherein the buffer layer comprises silicon nitride.

20. The semiconductor package of claim 17, wherein the second semiconductor chip further comprises:
a second protective insulating structure on the second semiconductor substrate; and
a second through electrode at least partially penetrating the second semiconductor substrate and the second protective insulating structure, and
wherein the second bonding pad is on a lower portion of the second through electrode.
